(19) United States
(12) Patent Application Publication
(10) Pub. No.: US 2012/0227809 A1
(43) Pub. Date: Sep. 13, 2012

(54) FLEXIBLE ASSEMBLY AND METHOD OF MAKING AND USING THE SAME

(76) Inventors: Vivek Bharti, Cottage Grove, MN (US); Timothy J. Hebrink, Scandia, MN (US); Andrew J. Henderson, Eagan, MN (US); Jay M. Jennen, Forest Lake, MN (US); Alan K. Nachtigal, Minneapolis, MN (US); Gregg A. Patnode, Woodbury, MN (US); Karl B. Richter, St. Paul, MN (US); Mark A. Roehrig, Stillwater, MN (US); Mark D. Weigel, Hugo, MN (US)

(21) Appl. No.: 13/510,644

(22) PCT Filed: Nov. 17, 2010
(86) PCT No.: PCT/US10/56933

§ 371 Date: May 18, 2012

Related U.S. Application Data
(60) Provisional application No. 61/262,406, filed on Nov. 18, 2009.
(60) Provisional application No. 61/262,417, filed on Nov. 18, 2009.

(51) Int. Cl. H01L 31/0203; C09J 123/22; B32B 27/00; B05D 5/10; H01L 31/18; H01L 31/0264

(52) U.S. Cl. 136/259; 438/57; 136/262; 428/339; 427/208.4; 428/220; 524/579; 257/E31.001

(57) ABSTRACT

An assembly including a pressure sensitive adhesive layer at least 0.25 mm in thickness disposed on a barrier assembly, wherein the barrier assembly comprises a polymeric film substrate and a barrier film. The assembly is flexible and transmissive to visible and infrared light. A pressure sensitive adhesive in the form of a film at least 0.25 mm thick is also provided, the pressure sensitive adhesive including a polyisobutylene having a weight average molecular weight less than 300,000 grams per mole; and a hydrogenated hydrocarbon tackifier. Methods of making and using the assembly and the pressure sensitive adhesive are also included.

### CROSS-REFERENCE TO RELATED APPLICATION

This application claims the benefit of U.S. Provisional Application Nos. 61/262,406, filed Nov. 18, 2009, and 61/262,417, filed Nov. 18, 2009, the disclosures of which are incorporated by reference herein in their entirety.

### BACKGROUND

Emerging solar technologies such as organic photovoltaic devices (OPVs) and thin film solar cells like copper indium gallium di-selenide (CIGS) require protection from water vapor and need to be durable (e.g., to ultra-violet (UV) light) in outdoor environments. Typically, glass has been used as an encapsulating material for such solar devices because glass is a very good barrier to water vapor, is optically transparent, and is stable to UV light. However, glass is heavy, brittle, difficult to make flexible, and difficult to handle. There is interest in developing transparent flexible encapsulating materials to replace glass that will not share the drawbacks of glass but have glass-like barrier properties and UV stability. Despite progress in encapsulant technology, the barrier and durability requirements in solar applications continue to be a challenge, and further work is needed to bring cost-effective, flexible encapsulating solutions to the solar market.

### SUMMARY

The present disclosure provides assemblies useful, for example, for encapsulating solar devices. The assemblies are generally flexible, transmissive to visible and infrared light, and free of added solvent and have excellent barrier properties. Also, conveniently, in some embodiments, the assemblies disclosed herein can be formed on a roll and can be applied, for example, to thin film solar cells using roll-to-roll processing at room temperature.

In one aspect, the present disclosure provides an assembly comprising a pressure sensitive adhesive layer at least 0.25 mm in thickness disposed on a barrier assembly, wherein the barrier assembly comprises a polymeric film substrate and a barrier film, and wherein the assembly is flexible and transmissive to visible and infrared light. In some embodiments, the assembly comprises a polymeric film substrate having a major surface; a barrier film having opposing first and second major surfaces, wherein the first major surface of the barrier film is disposed on (in some embodiments, in intimate contact with) the major surface of the polymeric film substrate; and a pressure sensitive adhesive layer at least 0.25 mm in thickness having opposing third and fourth major surfaces, wherein the third major surface of the pressure sensitive adhesive is disposed on (in some embodiments, in intimate contact with) the second major surface of the barrier film, wherein the assembly is flexible and transmissive to visible and infrared light.

In another aspect, the present disclosure provides a method of making the assembly disclosed herein, the method comprising providing the barrier assembly comprising the polymeric film substrate and the barrier film; extruding the pressure sensitive adhesive using solventless extrusion; and applying the pressure sensitive adhesive to the barrier assembly.

In another aspect, the present disclosure provides a pressure sensitive adhesive comprising a polyisobutylene having a weight average molecular weight less than 300,000 grams per mole; and a hydrogenated hydrocarbon tackifier, wherein the pressure sensitive adhesive is in the form of a film at least 0.25 mm thick.

In another aspect, the present disclosure provides a method of making a pressure sensitive adhesive, the method comprising hot melt extruding an extrudable composition comprising a polyisobutylene having a weight average molecular weight of at least 500,000 grams per mole and a hydrogenated hydrocarbon tackifier, wherein the hot melt extruding is carried out at a temperature sufficient to decrease the weight average molecular weight of the polyisobutylene resin to less than 300,000 grams per mole such that a pressure sensitive adhesive comprising a polyisobutylene resin having a weight average molecular weight less than 300,000 grams per mole and hydrogenated hydrocarbon tackifier is formed.

Adhesives used in barrier assemblies, for example, to attach a barrier film to a device (e.g., an organic electroluminescence device or a photovoltaic cell) have conventionally been made as thin as possible. For example, some adhesives in barrier assemblies are reported to have a thickness of at least 0.005 millimeters (mm) up to about 0.2 mm and thickness of 0.025 to 0.1 mm may be considered typical. Generally, it has been believed that such thicknesses minimize the opportunity for moisture to infiltrate an encapsulated device through the adhesive edge. Also, for some devices (e.g., organic electroluminescence devices) it is generally considered desirable to minimize the thickness of the encapsulated device. For example, U.S. Pat. No. 6,835,950 (Brown et al.) teaches that thin adhesives (e.g., up to 0.125 mm thick) minimize the differences in the radii of curvature between layers on opposite sides of the adhesive layer, thereby minimizing stresses that arise upon flexing the structure. Also, many adhesives used in barrier assemblies have been cast from solvent. Minimizing thickness in the adhesive has typically therefore been advantageous for the necessary removal of solvent during a drying step.

Thin-film photovoltaic cells (e.g., CIGS) have higher profiles than, for example, organic electroluminescence devices. Thin-film CIGS cells typically have bussing and tabbing ribbons that may, for example, stand more than 0.15 mm above the surface of the cell. Typically in the past, glass-encapsulated CIGS modules have been constructed using ethylene-vinyl acetate (EVA) crosslinked with peroxide initiators at elevated temperatures (e.g., 150° C.) in a batch vacuum lamination process that takes at least ten minutes. This type of adhesive and process is necessary for glass modules due to the mechanical support requirements of the heavy glass.

In contrast, the present disclosure provides a pressure sensitive adhesive (PSA) layer useful for attaching a barrier film on a polymeric film substrate to a thin-film photovoltaic cell, for example. The PSA and assemblies disclosed herein typically can be applied in a continuous process, do not require elevated temperature curing, and do not require the removal of solvent. Assemblies according to the present disclosure, which in some embodiments have thicknesses of at least 0.25 mm, are shown herein to have moisture resistance that is similar to a comparative assembly formed with a commercially available thermally cured encapsulant. The increased thickness of the adhesive in the assemblies disclosed herein is useful for providing an even topography over a thin-film photovoltaic device (e.g., CIGS). Furthermore, the assemblies disclosed herein have surprisingly better adhesion to a solar backsheet film after humidity exposure (e.g., 85° C. and 85% relative humidity (RH) for about 200 hours) than a comparative assembly formed with a commercially available thermally cured encapsulant.

In this application, terms such as “a”, “an” and “the” are not intended to refer to only a singular entity, but include the general class of which a specific example may be used for illustration. The terms “a”, “an”, and “the” are used interchangeably with the term “at least one”. The phrases “at least one of” and “comprises at least one of” followed by a list refers to any one of the items in the list and any combination of two or more items in the list. All numerical ranges are inclusive of their endpoints and non-integral values between the endpoints unless otherwise stated.

### BRIEF DESCRIPTION OF THE DRAWINGS

The disclosure may be more completely understood in consideration of the following detailed description of various embodiments of the disclosure in connection with the accompanying drawings, in which:

FIG. 1 illustrates an assembly according to some embodiments of the present disclosure using a schematic side view;

FIG. 2 illustrates a schematic side view of an embodiment of an assembly according to the present disclosure in which the barrier film has layers;

FIG. 3A illustrates a schematic side view of another embodiment of an assembly according to the present disclosure in which the assembly includes a release liner;

FIG. 3B illustrates a schematic side view of an embodiment of an assembly according to the present disclosure in which the barrier film has layers and in which the assembly includes a release liner;

FIG. 4A illustrates a schematic side view of another embodiment of an assembly according to the present disclosure in which the assembly includes a photovoltaic module;

FIG. 4B illustrates a schematic side view of an embodiment of an assembly according to the present disclosure in which the barrier film has layers and in which the assembly includes a photovoltaic module;

FIG. 5 is a schematic illustration of an apparatus for roll-to-roll processing of an assembly according to an embodiment of the present disclosure; and

FIG. 6 is a schematic illustration of an apparatus for applying a pressure sensitive adhesive to a barrier film and substrate according to another embodiment of the present disclosure.

### DETAILED DESCRIPTION

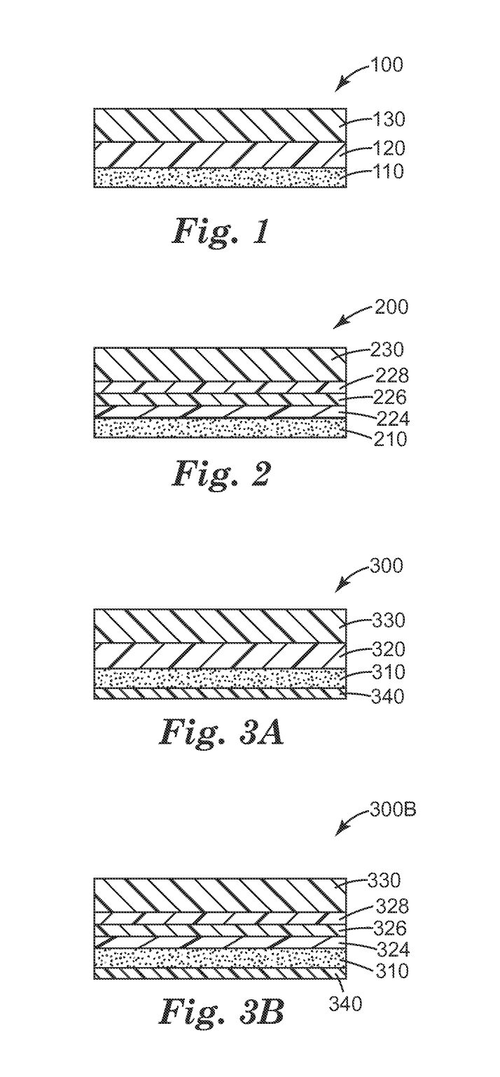

Assemblies according to the present disclosure are flexible and transmissive to visible and infrared light. The term “flexible” as used herein refers to being capable of being formed into a roll. In some embodiments, the term “flexible” refers to being capable of being bent around a roll core with a radius of curvature of up to 7.6 centimeters (cm) (3 inches), in some embodiments up to 6.4 cm (2.5 inches), 5 cm (2 inches), 3.8 cm (1.5 inch), or 2.5 cm (1 inch). In some embodiments, the flexible assembly can be bent around a radius of curvature of at least 0.635 cm (¼ inch), 1.3 cm (½ inch) or 1.9 cm (¾ inch). The term “transmissive to visible and infrared light” as used herein can mean having an average transmission over the visible and infrared portion of the spectrum of at least about 75% (in some embodiments at least about 80, 85, 90, 92, 95, 97, or 98%) measured along the normal axis. In some embodiments, the visible and infrared light-transmissive assembly has an average transmission over a range of 400 nm to 1400 nm of at least about 75% (in some embodiments at least about 80, 85, 90, 92, 95, 97, or 98%). Visible and infrared light-transmissive assemblies are those that do not interfere with absorption of visible and infrared light, for example, by photovoltaic cells. In some embodiments, the visible and infrared light-transmissive assembly has an average transmission over a range of wavelengths of light that are useful to a photovoltaic cell of at least about 75% (in some embodiments at least about 80, 85, 90, 92, 95, 97, or 98%). Flexible, visible and infrared light-transmissive assemblies according to the present disclosure are illustrated in FIG. 1 to 4.

FIG. 1 illustrates an assembly according to some embodiments of the present disclosure. Assembly 100 includes a polymeric film substrate 130. Substrate 130 has a major surface that is in intimate contact with a first major surface of barrier film 120. The second major surface of barrier film 120 is in intimate contact with a pressure sensitive adhesive layer 110.

FIG. 2 illustrates another assembly 200 according to some embodiments of the present disclosure, in which the barrier film has layers 228, 226, and 224. In the illustrated embodiment, first and second polymer layers 228 and 224 are separated by a visible light-transmissive inorganic barrier layer 226, which is in intimate contact with the first and second polymer layers 228 and 224. In the illustrated embodiment, the first polymer layer 228 is in contact with the major surface of the polymeric film substrate 230, and the second polymer layer 224 is in intimate contact with the pressure sensitive adhesive 210.

In FIG. 3A, assembly 300 is similar to assembly 100 and includes polymeric film substrate 330, barrier film 320, and pressure sensitive adhesive 310 in intimate contact with the second major surface of the barrier film 320. In FIG. 3B, the barrier film has layers 328, 326, and 324 similar to assembly 200. A release liner 340 protects the pressure sensitive adhesive on the surface opposite the barrier film 320 or second polymer layer 324. The release liner 340 is typically removed before assembly 300 is applied to a surface in need of encapsulation (e.g., a photovoltaic cell).

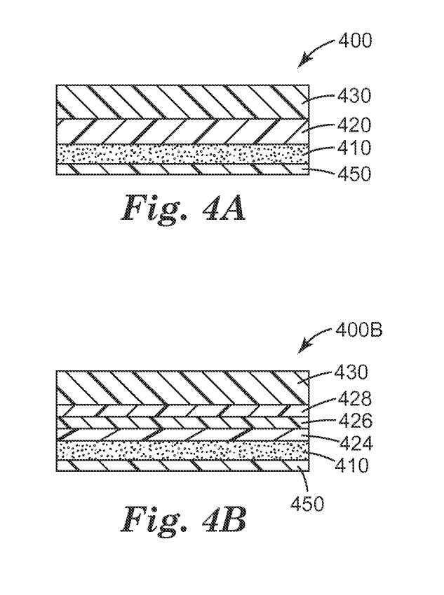

In FIG. 4A, assembly 400 is similar to assembly 100 and includes polymeric film substrate 430, barrier film 420, and pressure sensitive adhesive 410 in intimate contact with the second major surface of the barrier film 420. In FIG. 4B, the barrier film has layers 428, 426, and 424 similar to assembly 200. In the illustrated embodiments, the assembly 400 or 400B is applied to a photovoltaic cell 450 (e.g., a thin-film CIGS cell).

In FIGS. 1 to 4, the PSA 110, 210, 310, and 410 and polymeric film substrate 130, 230, 330, and 430 are shown on opposite sides of the barrier film. It is also envisioned that the positions of the barrier film and the polymeric film substrate could be reversed.

Polymeric film substrates 130, 230, 330, 430; barrier film 120, 320, 420; pressure sensitive adhesive 110, 210, 310, 410; release liner 340; and substrates in need of encapsulation 450 useful for practicing the present disclosure are described in more detail below. In some embodiments of the assemblies disclosed herein, a pressure sensitive adhesive disclosed herein is disposed on a barrier assembly. In these embodiments, the barrier assembly is part of the assembly and comprises the polymeric film substrates and the barrier film described below. Accordingly, the description that follows refers to polymeric film substrates and barrier films that may be in an assembly according to the present disclosure, a barrier assembly useful for practicing the present disclosure, or both.

### Polymeric Film Substrate

Assemblies according to the present disclosure comprise a polymeric film substrate 130, 230, 330, 430. In this context, the term “polymeric” will be understood to include organic homopolymers and copolymers, as well as polymers or copolymers that may be formed in a miscible blend, for example, by co-extrusion or by reaction, including transesterification. The terms “polymer” and “copolymer” include both random and block copolymers. The polymeric film substrate is generally flexible and transmissive to visible and infrared light and comprises organic film-forming polymers. Useful materials that can form polymeric film substrates include polyesters, polycarbonates, polyethers, polyimides, polyolefins, fluoropolymers, and combinations thereof.

In embodiments wherein the assembly according to the present disclosure is used, for example, for encapsulating solar devices, it is typically desirable for the polymeric film substrate to be resistant to degradation by ultraviolet (UV) light and weatherable. Photo-oxidative degradation caused by UV light (e.g., in a range from 280 to 400 nm) may result in color change and deterioration of optical and mechanical properties of polymeric films. A variety of stabilizers may be added to the polymeric film substrate to improve its resistance to UV light. Examples of such stabilizers include at least one of ultra violet absorbers (UVA) (e.g., red shifted UV absorbers), hindered amine light stabilizers (HALS), or anti-oxidants. These additives are described in further detail below.

In some embodiments, the polymeric film substrates disclosed herein comprise a fluoropolymer. Fluoropolymers typically are resistant to UV degradation even in the absence of stabilizers such as UVA, HALS, and anti-oxidants. Useful fluoropolymers include ethylene-tetrafluoroethylene copolymers (ETFE), tetrafluoroethylene-hexafluoropropylene copolymers (FEP), tetrafluoroethylene-hexafluoropropylene-vinylidene fluoride copolymers (THV), polyvinylidene fluoride (PVDF), blends thereof, and blends of these and other fluoropolymers. The substrates comprising fluoropolymer can also include non-fluorinated materials. For example, a blend of polyvinylidene fluoride and polymethyl methacrylate can be used. Useful flexible, visible and infrared light-transmissive substrates also include multi-layer film substrates. Multi-layer film substrates may have different fluoropolymers in different layers or may include at least one layer of fluoropolymer and at least one layer of a non-fluorinated polymer. Multi-layer films can comprise a few layers (e.g., at least 2 or 3 layers) or can comprise at least 100 layers (e.g., in a range from 100 to 2000 total layers or more). The different polymers in the different multi-layer film substrates can be selected, for example, to reflect a significant portion (e.g., at least 30, 40, or 50%) of UV light in a wavelength range from 300 to 400 nm as described, for example, in U.S. Pat. No. 5,540,978 (Schrenk).

Useful substrates comprising a fluoropolymer can be commercially obtained, for example, from E.I. duPont De Nemours and Co., Wilmington, Del., under the trade designation “TEFZEL ETFE” and “TEDLAR”, from Dyneon LLC, Oakdale, Minn., under the trade designations “DYNEON ETFE”, “DYNEON THV”, “DYNEON FEP”, and “DYNEON PVDF”, from St. Gobain Performance Plastics, Wayne, N.J., under the trade designation “NORTON ETFE”, from Asahi Glass under the trade designation “CYTOPS”, and from Denka Kagaku Kogyo KK, Tokyo, Japan under the trade designation “DENKA DX FILM”.

In some embodiments, the polymeric film substrate useful for practicing the present disclosure comprises a multi-layer optical film. In some embodiments, the polymeric film substrate comprises an ultraviolet-reflective multilayer optical film having first and second major surfaces and comprising an ultraviolet-reflective optical layer stack, where the ultraviolet-reflective optical layer stack comprises first optical layers and second optical layers, wherein at least a portion of the first optical layers and at least a portion of the second optical layers are in intimate contact and have different refractive indexes, and wherein the multilayer optical film further comprises a ultraviolet absorber in at least one of the first optical layer, the second optical layer, or a third layer disposed on at least one of the first or second major surfaces of the ultraviolet reflective multilayer optical film. In some embodiments, the multilayer optical film comprises at least a plurality of first and second optical layers collectively reflecting at least 50 (in some embodiments, at least 55, 60, 65, 70, 75, 80, 85, 90, 95, 96, 97, or even at least 98) percent of incident UV light over at least a 30 (in some embodiments, at least 35, 40, 45, 50, 55, 60, 65, 70, 75, 80, 85, 90, 95, or even at least 100) nanometer wavelength range in a wavelength range from at least 300 nanometers to 400 nanometers, wherein some of at least one of the first or second optical layers (in some embodiments at least 50 percent by number of the first and/or second layers, in some embodiments all of at least one of the first or second layers) comprises a UV absorber. In some embodiments, the polymeric film substrate useful for practicing the present disclosure is a multi-layer optical film comprising a plurality of at least first and second optical layers having a major surface and collectively reflecting at least 50 (in some embodiments, at least 55, 60, 65, 70, 75, 80, 85, 90, 95, 96, 97, or even at least 98) percent of incident UV light over at least a 30 (in some embodiments, at least 35, 40, 45, 50, 55, 60, 65, 70, 75, 80, 85, 90, 95, or even at least 100) nanometer wavelength range in a wavelength range from at least 300 nanometers to 400 nanometers, and a third optical layer having first and second generally opposed first and second major surfaces and absorbing at least 50 (in some embodiments, at least 55, 60, 65, 70, 75, 80, 85, 90, or even at least 95) percent of incident UV light over at least a 30 (in some embodiments, at least 35, 40, 45, 50, 55, 60, 65, 70, 75, 80, 85, 90, 95, or even at least 100) nanometer wavelength range in a wavelength range from at least 300 nanometers to 400 nanometers, wherein the major surface of the plurality of first and second optical layers is proximate (i.e., not more than 1 mm, in some embodiments, not more than 0.75 mm, 0.5 mm, 0.4, mm, 0.3, mm, 0.25 mm, 0.2 mm, 0.15 mm, 0.1 mm, or even not greater than 0.05 mm; in some embodiments, contacting) to the first major surface of the third optical layer, and wherein there is not another multi-layer optical film proximate the second surface of the third optical layer. Optionally, the first and/or second layers comprise a UV absorber. In some embodiments the polymeric film substrate useful for practicing the present disclosure is a multi-layer optical film comprising a first plurality of at least first and second optical layers having a major surface and collectively reflecting at least 50 (in some embodiments, at least 55, 60, 65, 70, 75, 80, 85, 90, 95, 96, 97, or even at least 98) percent of incident UV light over at least a 30 (in some embodiments, at least 35, 40, 45, 50, 55, 60, 65, 70, 75, 80, 85, 90, 95, or even at least 100) nanometer wavelength range in a wavelength range from at least 300 nanometers to 400 nanometers, and a third optical layer having first and second generally opposed first and second major surfaces and collectively absorbing at least 50 (in some embodiments, at least 55, 60, 65, 70, 75, 80, 85, 90, or even at least 95) percent of incident UV light over at least a 30 (in some embodiments, at least 35, 40, 45, 50, 55, 60, 65, 70, 75, 80, 85, 90, 95, or even at least 100) nanometer wavelength range in a wavelength range from at least 300 nanometers to 400 nanometers, wherein the major surface of the plurality of first and second optical layers is proximate (i.e., within 1 mm, in some embodiments, not more than 0.75 mm, 0.5 mm, 0.4, mm, 0.3, mm, 0.25 mm, 0.2 mm, 0.15 mm, 0.1 mm, or even within 0.05 mm; in some embodiments, contacting) to the first major surface of the third optical layer, and wherein there is a second plurality of first and second optical layers having a major surface and collectively reflecting at least 50 (in some embodiments, at least 55, 60, 65, 70, 75, 80, 85, 90, 95, 96, 97, or even at least 98) percent of incident UV light over at least a 30 (in some embodiments, at least 35, 40, 45, 50, 55, 60, 65, 70, 75, 80, 85, 90, 95, or even at least 100) nanometer wavelength range in a wavelength range from at least 300 nanometers to 400 nanometers proximate (i.e., within 1 mm, in some embodiments, not more than 0.75 mm, 0.5 mm, 0.4, mm, 0.3, mm, 0.25 mm, 0.2 mm, 0.15 mm, 0.1 mm, or even within 0.05 mm; in some embodiments, contacting) to the second major surface of the third optical layer. Optionally, the first and/or second layers comprise a UV absorber. In some embodiments, the polymeric film substrate useful for practicing the present disclosure is a multi-layer optical film comprising a plurality of at least first and second optical layers having opposing first and second major surfaces and collectively reflecting at least 50 (in some embodiments, at least 55, 60, 65, 70, 75, 80, 85, 90, 95, 96, 97, or even at least 98) percent of incident UV light over at least a 30 (in some embodiments, at least 35, 40, 45, 50, 55, 60, 65, 70, 75, 80, 85, 90, 95, or even at least 100) nanometer wavelength range in a wavelength range from at least 300 nanometers to 400 nanometers, a third optical layer having a major surface and absorbing at least 50 (in some embodiments, at least 55, 60, 65, 70, 75, 80, 85, 90, or even at least 95) percent of incident UV light over at least a 30 (in some embodiments, at least 35, 40, 45, 50, 55, 60, 65, 70, 75, 80, 85, 90, 95, or even at least 100) nanometer wavelength range in a wavelength range from at least 300 nanometers to 400 nanometers proximate (i.e., within 1 mm, in some embodiments, not more than 0.75 mm, 0.5 mm, 0.4, mm, 0.3, mm, 0.25 mm, 0.2 mm, 0.15 mm, 0.1 mm, or even within 0.05 mm; in some embodiments, contacting) to the first major surface of the plurality of at least first and second optical layers, and a fourth optical layer absorbing at least 50 (in some embodiments, at least 55, 60, 65, 70, 75, 80, 85, 90, or even at least 95) percent of incident UV light over at least a 30 (in some embodiments, at least 35, 40, 45, 50, 55, 60, 65, 70, 75, 80, 85, 90, 95, or even at least 100) nanometer wavelength range in a wavelength range from at least 300 nanometers to 400 nanometers proximate (i.e., within 1 mm, in some embodiments, not more than 0.75 mm, 0.5 mm, 0.4, mm, 0.3, mm, 0.25 mm, 0.2 mm, 0.15 mm, 0.1 mm, or even within 0.05 mm; in some embodiments, contacting) to the second major surface of the plurality of at least first and second optical layers. Optionally, the first and/or second layers comprise a UV absorber. In some embodiments, the polymeric film substrate useful for practicing the present disclosure comprises a multi-layer optical film comprising at least first and second optical layers reflecting at least 50 (in some embodiments, at least 55, 60, 65, 70, 75, 80, 85, 90, 95, 96, 97, or even at least 98) percent of incident light over a 30 (in some embodiments, at least 35, 40, 45, 50, 55, 60, 65, 70, 75, 80, 85, 90, 95, 100, 110, 120, or even at least 130) nanometer wavelength range in a wavelength range from 300 nanometers to 430 nanometers, optionally a third optical layer absorbing at least 50 (in some embodiments, at least 55, 60, 65, 70, 75, 80, 85, 90, or even at least 95) percent of incident light over at least a 30 (in some embodiments, at least 35, 40, 45, 50, 55, 60, 65, 70, 75, 80, 85, 90, 95, 100, 110, 120, or even at least 130) nanometer wavelength range in a wavelength range from at least 300 nanometers to 430 nanometers and a fourth optical layer comprising polyethylene naphthalate, wherein at least one of the first, second, or third optical layers absorbs at least 50 percent of incident light over at least a 30 (in some embodiments, at least 35, 40, 45, 50, 55, 60, 65, 70, 75, 80, 85, 90, 95, 100, 110, 120, or even at least 130) nanometer wavelength range in a wavelength range from at least 300 nanometers to 430 nanometers. Optionally, the first and/or second layers comprise a UV absorber. In some embodiments, a plurality of the fourth optical layers collectively absorb at least 50 (in some embodiments, at least 55, 60, 65, 70, 75, 80, 85, 90, or even at least 95) percent of incident light over at least 30, 35, 40, 45, 50, 75, 100, 150, 200, 250, 300, 350, 400, 450, 500, 600, 700, 800, 900, 1000, 1100, 1200, 1300, 1400, 1500, 1600, 1700, 1800, 1900, 2000, or even 2100) nanometer wavelength range in a wavelength range from 400 nanometers to 2500 nanometers.

For multi-layer optical films described herein, the first and second layers (in some embodiments, alternating first and second optical layers) of the multilayer optical films typically have a difference in refractive index of at least 0.04 (in some embodiments, at least 0.05, 0.06, 0.07, 0.08, 0.09. 0.1, 0.125, 0.15, 0.175, 0.2, 0.225, 0.25, 0.275, or even at least 0.3). In some embodiments, the first optical layer is birefringent and comprises a birefringent polymer. The layer thickness profile (layer thickness values) of multi-layer optical film described herein reflecting at least 50 percent of incident UV light over a specified wavelength range can be adjusted to be approximately a linear profile with the first (thinnest) optical layers adjusted to have about a ¼ wave optical thickness (index times physical thickness) for 300 nm light and progressing to the thickest layers which would be adjusted to be about ¼ wave thick optical thickness for 420 nm light. Light that is not reflected at the interface between adjacent optical layers typically passes through successive layers and is either reflected at a subsequent interface or passes through the UV-reflective optical layer stack altogether.

The normal reflectivity for a particular layer pair is primarily dependent on the optical thickness of the individual layers, where optical thickness is defined as the product of the actual thickness of the layer times its refractive index. The intensity of light reflected from the optical layer stack is a function of its number of layer pairs and the differences in refractive indices of optical layers in each layer pair. The ratio n₁d₁/(n₁d₂+n₂d₂) (commonly termed the “f-ratio”) correlates with reflectivity of a given layer pair at a specified wavelength. In the f-ratio, n₁ and n₂ are the respective refractive indexes at the specified wavelength of the first and second optical layers in a layer pair, and d₁ and d₂ are the respective thicknesses of the first and second optical layers in the layer pair. By proper selection of the refractive indexes, optical layer thicknesses, and f-ratio one can exercise some degree of control over the intensity of first order reflection.

The equation λ/2=n₁d₁+n₂d₂ can be used to tune the optical layers to reflect light of wavelength λ at a normal angle of incidence. At other angles, the optical thickness of the layer pair depends on the distance traveled through the component optical layers (which is larger than the thickness of the layers) and the indices of refraction for at least two of the three optical axes of the optical layer. The optical layers can each be a quarter-wavelength thick or the optical thin layers can have different optical thicknesses, as long as the sum of the optical thicknesses is half of a wavelength (or a multiple thereof). An optical stack having more than two layer pairs can include optical layers with different optical thicknesses to provide reflectivity over a range of wavelengths. For example, an optical stack can include layer pairs that are individually tuned to achieve optimal reflection of normally incident light having particular wavelengths or may include a gradient of layer pair thicknesses to reflect light over a larger bandwidth. A typical approach is to use all or mostly quarter-wave film stacks. In this case, control of the spectrum requires control of the layer thickness profile in the film stack.

Desirable techniques for providing a multilayer optical film with a controlled spectrum include the use of an axial rod heater control of the layer thickness values of coextruded polymer layers as described, for example, in U.S. Pat. No. 6,783,349 (Neavin et al.), the disclosure of which is incorporated herein by reference; timely layer thickness profile feedback during production from a layer thickness measurement tool such as an atomic force microscope (AFM), a transmission electron microscope, or a scanning electron microscope; optical modeling to generate the desired layer thickness profile; and repeating axial rod adjustments based on the difference between the measured layer profile and the desired layer profile.

The basic process for layer thickness profile control involves adjustment of axial rod zone power settings based on the difference of the target layer thickness profile and the measured layer profile. The axial rod power increase needed to adjust the layer thickness values in a given feedblock zone may first be calibrated in terms of watts of heat input per nanometer of resulting thickness change of the layers generated in that heater zone. For example, fine control of the spectrum is possible using 24 axial rod zones for 275 layers. Once calibrated, the necessary power adjustments can be calculated once given a target profile and a measured profile. The procedure is repeated until the two profiles converge.

Exemplary materials for making the optical layers that reflect (e.g., the first and second optical layers) include polymers and polymer blends (e.g., polyesters, copolyesters, modified copolyesters, and polycarbonates). Polyesters can be made, for example, from ring-opening addition polymerization of a lactone or by condensation of a dicarboxylic acid (or derivative thereof such as a diacid halide or a diester) with a diol. The dicarboxylic acid or dicarboxylic acid derivative molecules may all be the same or there may be two or more different types of molecules. The same applies to the diol monomer molecules. Polycarbonates can be made, for example, from the reaction of diols with esters of carbonic acid.

Examples of suitable dicarboxylic acid molecules for use in forming polyesters include 2,6-naphthalene dicarboxylic acid and isomers thereof; terephthalic acid; isophthalic acid; phthalic acid; azelaic acid; adipic acid; sebacic acid; norbornenedicarboxylic acid; bicyclooctane dicarboxylic acid; 1,6-cyclohexanedicarboxylic acid and isomers thereof; t-butyl isophthalic acid, trimellitic acid, sodium sulfonated isophthalic acid; 4,4′-biphenyl dicarboxylic acid and isomers thereof. Acid halides and lower alkyl esters of these acids, such as methyl or ethyl esters, may also be used as functional equivalents. The term “lower alkyl” refers, in this context, to C1-C10 straight-chained or branched alkyl groups. Examples of suitable diols for use in forming polyesters include ethylene glycol; propylene glycol; 1,4-butanediol and isomers thereof 1,6-hexanediol; neopentyl glycol; polyethylene glycol; diethylene glycol; tricyclodecanediol; 1,4-cyclohexanedimethanol and isomers thereof norbornanediol; bicyclooctanediol; trimethylol propane; pentaerythritol; 1,4-benzenedimethanol and isomers thereof; bisphenol A; 1,8-dihydroxy biphenyl and isomers thereof; and 1,3-bis(2-hydroxyethoxy)benzene.

Exemplary birefringement polymers useful for the reflective layer(s) include polyethylene terephthalate (PET). Its refractive index for polarized incident light of 550 nm wavelength increases when the plane of polarization is parallel to the stretch direction from about 1.57 to as high as about 1.69. Increasing molecular orientation increases the birefringence of PET. The molecular orientation may be increased by stretching the material to greater stretch ratios and holding other stretching conditions fixed. Copolymers of PET (CoPET), such as those described in U.S. Pat. No. 6,744,561 (Condo et al.) and U.S. Pat. No. 6,449,093 (Hebrink et al.), the disclosures of which are incorporated herein by reference, are particularly useful for their relatively low temperature (typically less than 250° C.) processing capability making them more coextrusion compatible with less thermally stable second polymers. Other semicrystalline polyesters suitable as birefringent polymers include polybutylene 2,6-terephthalate (PBT), polyethylene terephthalate (PET), and copolymers thereof such as those described in U.S. Pat. No. 6,449,093 B2 (Hebrink et al.) or U.S. Pat. Pub. No. 20060084780 (Hebrink et al.), the disclosures of which are incorporated herein by reference. Other useful birefringent polymers include syndiotactic polystyrene (sPS); polyethylene 2,6-naphthalates (PENs); copolyesters derived from naphthalenedicarboxylic acid, an additional dicarboxylic acid, and a diol (coPENs) (e.g., a polyester derived through co-condensation of 90 equivalents of dimethyl naphthalenedicarboxylate, 10 equivalents of dimethyl terephthalate, and 100 equivalents of ethylene glycol, and having an intrinsic viscosity (IV) of 0.48 dL/g, and an index of refraction is approximately 1.63); polyether imides; and polyester/non-polyester combinations; polybutylene 2,6-naphthalates (PBNs); modified polyolefin elastomers, e.g., as available as ADMER (e.g., ADMER SE810) thermoplastic elastomers from Mitsui Chemicals America, Inc. of Rye Brook, N.Y.; and thermoplastic polyurethanes (TPUs) (e.g., as available as ELASTOLLAN TPUs from BASF Corp. of Florham Park, N.J. and as TECOFLEX or STATRITE TPUs (e.g., STATRITE X5091 or STATRITE M809) from The Lubrizol Corp. of Wickliffe, Ohio).

Further, for example, the second polymer (layer) of the multilayer optical film can be made from a variety of polymers having glass transition temperatures compatible with that of the first layer and having a refractive index similar to the isotropic refractive index of the birefringent polymer. Examples of other polymers suitable for use in optical films and, particularly, in the second polymer include vinyl polymers and copolymers made from monomers such as vinyl naphthalenes, styrene, maleic anhydride, acrylates, and methacrylates. Examples of such polymers include polyacrylates, polymethacrylates, such as poly(methyl methacrylate) (PMMA), and isotactic or syndiotactic polystyrene. Other polymers include condensation polymers such as polysulfones, polyamides, polyurethanes, polyamic acids, and polyimides. In addition, the second polymer can be formed from homopolymers and copolymers of polyesters, polycarbonates, fluoropolymers, and polydimethylsiloxanes, and blends thereof.

Many exemplary polymers for the optical layers, especially for use in the second layer, are commercially available and include homopolymers of polymethylmethacrylate (PMMA), such as those available from Ineos Acrylics, Inc., Wilmington, Del., under the trade designations “CP71” and “CP80;” and polyethyl methacrylate (PEMA), which has a lower glass transition temperature than PMMA. Additional useful polymers include copolymers of PMMA (CoPMMA), such as a CoPMMA made from 75 wt % methylmethacrylate (MMA) monomers and 25 wt % ethyl acrylate (EA) monomers, (available from Ineos Acrylics, Inc., under the trade designation “PERSPEX CP63” or Arkema, Philadelphia, Pa., under the trade designation “ATOGLAS 510”), a CoPMMA formed with MMA comonomer units and n-butyl methacrylate (nBMA) comonomer units, or a blend of PMMA and poly(vinylidene fluoride) (PVDF). Additional suitable polymers for the optical layers, especially for use in the second layer, include polyolefin copolymers such as poly(ethylene-co-octene) (PE-PO) available from Dow Elastomers, Midland, Mich., under the trade designation “ENGAGE 8200,” poly(propylene-co-ethylene) (PPPE) available from Atofina Petrochemicals, Inc., Houston, Tex., under the trade designation “Z9470,” and a copolymer of atactic polypropylene (aPP) and isotactic polypropylene (iPP). The multilayer optical films can also include, for example, in the second layers, a functionalized polyolefin, such as linear low density polyethylene-g-maleic anhydride (LLDPE-g-MA) such as that available from E.I. duPont de Nemours & Co., Inc., Wilmington, Del., under the trade designation “BYNEL 4105.”

The third optical layer, if present, comprises a polymer and a UV-absorber and can serve as a UV protective layer. Typically, the polymer is a thermoplastic polymer. Examples of suitable polymers include polyesters (e.g., polyethylene terephthalate), fluoropolymers, acrylics (e.g., polymethyl methacrylate), silicone polymers (e.g., thermoplastic silicone polymers), styrenic polymers, polyolefins, olefinic copolymers (e.g., copolymers of ethylene and norbornene available as “TOPAS COC” from Topas Advanced Polymers of Florence, Ky.), silicone copolymers, fluoropolymers, and combinations thereof (e.g., a blend of polymethyl methacrylate and polyvinylidene fluoride).

Exemplary polymer compositions for the third layer and/or second layers in alternating layers with the at least one birefringent polymer include PMMA, CoPMMA, polydimethyl siloxane oxamide based segmented copolymer (SPOX), fluoropolymers including homopolymers such as PVDF and copolymers such as those derived from tetrafluoroethylene, hexafluoropropylene, and vinylidene fluoride (THV), blends of PVDF/PMMA, acrylate copolymers, styrene, styrene copolymers, silicone copolymers, polycarbonate, polycarbonate copolymers, polycarbonate blends, blends of polycarbonate and styrene maleic anhydride, and cyclic-olefin copolymers.

The selection of the polymer combinations used in creating the multilayer optical film depends, for example, upon the desired bandwidth that will be reflected. Higher refractive index differences between the birefringent polymer and the second polymer create more optical power thus enabling more reflective bandwidth. Alternatively, additional layers may be employed to provide more optical power. Preferred combinations of birefringent layers and second polymer layers may include, for example, the following: PET/THV, PET/SPOX, PEN/THV, PEN/SPOX, PEN/PMMA, PET/CoPMMA, PEN/CoPMMA, CoPEN/PMMA, CoPEN/SPOX, sPS/SPOX, sPS/THV, CoPEN/THV, PET/fluoroelastomers, sPS/fluoroelastomers and CoPEN/fluoroelastomers.

In some embodiments, material combinations for making the optical layers that reflect UV light (e.g., the first and second optical layers) include PMMA and THV, and PET and/CoPMMA. Exemplary material for making the optical layers that absorb UV light (e.g., the third optical layer) include PET, CoPMMA, or blends of PMMA and PVDF.

A UV absorbing layer (e.g., a UV protective layer) aids in protecting the visible/IR-reflective optical layer stack from UV-light caused damage/degradation over time by absorbing UV-light (preferably any UV-light) that may pass through the UV-reflective optical layer stack. In general, the UV-absorbing layer(s) may include any polymeric composition (i.e., polymer plus additives) that is capable of withstanding UV-light for an extended period of time. A variety of optional additives may be incorporated into an optical layer to make it UV absorbing. Examples of such additives include at least one of UV absorbers (UVAs), HALS, or anti-oxidants. Typical UV absorbing layers have thicknesses in a range from 13 micrometers to 380 micrometers (0.5 mil to 15 mil) with a UVA loading level of 2-10% by weight.

A UVA is typically a compound capable of absorbing or blocking electromagnetic radiation at wavelengths less than 400 nm while remaining substantially transparent at wavelengths greater than 400 nm. Such compounds can intervene in the physical and chemical processes of photoinduced degradation. UVAs are typically included in a UV absorbing layer in an amount sufficient to absorb at least 70% (in some embodiments, at least 80%, or greater than 90% of the UV light in the wavelength region from 180 nm to 400 nm). Typically, it is desirable if the UVA is highly soluble in polymers, highly absorptive, photo-permanent and thermally stable in the temperature range from 200° C. to 300° C. for extrusion process to form the protective layer. The UVA can also be highly suitable if they can be copolymerizable with monomers to form protective coating layer by UV curing, gamma ray curing, e-beam curing, or thermal curing processes.

Red-shifted UVAs (RUVAs) typically have enhanced spectral coverage in the long-wave UV region, enabling it to block the high wavelength UV light that can cause yellowing in polyesters. One of the most effective RUVAs is a benzotriazole compound, 5-trifluoromethyl-2-(2-hydroxy-3-alpha-cumyl-5-tert-octylphenyl)-2H-benzotriazole (sold under the trade designation “CGL-0139” from Ciba Specialty Chemicals Corporation, Tarryton, N.Y.). Other exemplary benzotriazoles include 2-(2-hydroxy-3,5-di-alpha-cumylphehyl)-2H-benzotriazole, 5-chloro-2-(2-hydroxy-3-tert-butyl-5-methylphenyl)-2H-benzothiazole, 5-chloro-2-(2-hydroxy-3,5-di-tert-butylphenyl)-2H-benzotriazole, 2-(2-hydroxy-3,5-di-tert-amylphenyl)-2H-benzotriazole, 2-(2-hydroxy-3-alpha-cumyl-5-tert-octylphenyl)-2H-benzotriazole, 2-(3-tert-butyl-2-hydroxy-5-methylphenyl)-5-chloro-2H-benzotriazole. Further exemplary RUVA includes 2(-4,6-diphenyl-1-3,5-triazin-2-yl)-5-hekyloxy-phenol. Other exemplary UV absorbers include those available from Ciba Specialty Chemicals Corporation under the trade designation “TINUVIN 1577,” “TINUVIN 900,” and “TINUVIN 777.” Another exemplary UV absorber is available in a polyester master batch from Sukano Polymers Corporation, Dunkin S.C., under the trade designation “TA07-07 MB”. Another exemplary UV absorber is available in a polycarbonate master batch from Sukano Polymers Corporation under the trade designation “TA28-09 MB”. In addition, the UV absorbers can be used in combination with hindered amine light stabilizers (HALS) and anti-oxidants. Exemplary HALS include those available from Ciba Specialty Chemicals Corporation, under the trade designation “CHIMASSORB 944” and “TINUVIN 123.” Exemplary anti-oxidants include those obtained under the trade designations “IRGAFOS 126”, “IRGANOX 1010” and “ULTRANOX 626”, also available from Ciba Specialty Chemicals Corporation.

The desired thickness of a UV protective layer is typically dependent upon an optical density target at specific wavelengths as calculated by Beers Law. In some embodiments, the UV protective layer has an optical density greater than 3.5, 3.8, or 4 at 380 nm; greater than 1.7 at 390 nm; and greater than 0.5 at 400 nm. Those of ordinary skill in the art recognize that the optical densities typically should remain fairly constant over the extended life of the film in order to provide the intended protective function.

The UV protective layer and any optional additives may be selected to achieve the desired protective functions such as UV protection. Those of ordinary skill in the art recognize that there are multiple means for achieving the noted objectives of the UV protective layer. For example, additives that are very soluble in certain polymers may be added to the composition. Of particular importance, is the permanence of the additives in the polymer. The additives should not degrade or migrate out of the polymer. Additionally, the thickness of the layer may be varied to achieve desired protective results. For example, thicker UV protective layers would enable the same UV absorbance level with lower concentrations of UV absorbers, and would provide more UV absorber permanence attributed to less driving force for UV absorber migration.

For additional details on multi-layer optical films that may be useful as polymeric film substrates (e.g., UV mirrors), see, for example, PCT Int. Appl. Pub. No. WO 2010/078105 (Hebrink et al.) and U.S. Ser. No. 61/262,417, filed on Nov. 18, 2009, the disclosures of which are incorporated herein by reference.

For any of the embodiments of the polymeric film substrate described above, the major surface of the polymeric film substrate to be joined with the barrier film disclosed herein can be treated to improve adhesion to the barrier film. Useful surface treatments include electrical discharge in the presence of a suitable reactive or non-reactive atmosphere (e.g., plasma, glow discharge, corona discharge, dielectric barrier discharge or atmospheric pressure discharge); chemical pretreatment; or flame pretreatment. A separate adhesion promotion layer may also be formed between the major surface of the polymeric film substrate and the barrier film. The adhesion promotion layer can be, for example, a separate polymeric layer or a metal-containing layer such as a layer of metal, metal oxide, metal nitride or metal oxynitride. The adhesion promotion layer may have a thickness of a few nanometers (nm) (e.g., 1 or 2 nm) to about 50 nm or more. Some useful polymeric film substrates that are surface treated are commercially available, for example, from St. Gobain Performance Plastics under the trade designation “NORTON ETFE”.

In some embodiments, the polymeric film substrate has a thickness from about 0.01 mm to about 1 mm, in some embodiments, from about 0.05 mm to about 0.25 mm. Thicknesses outside these ranges may also be useful, depending on the application.

The polymeric film substrates described herein can provide, for example, a durable, weatherable topcoat for a photovoltaic device. The substrates are generally abrasion and impact resistant and can prevent degradation of, for example, photovoltaic devices when they are exposed to outdoor elements. The weatherability of the polymeric film substrate can be evaluated, for example, using accelerated weathering studies. Accelerated weathering studies are generally performed on films using techniques similar to those described in ASTM G-155, “Standard practice for exposing non-metallic materials in accelerated test devices that use laboratory light sources”. The noted ASTM technique is considered as a sound predictor of outdoor durability, that is, ranking materials performance correctly. One mechanism for detecting the change in physical characteristics is the use of the weathering cycle described in ASTM G155 and a D65 light source operated in the reflected mode. Under the noted test, and when the UV protective layer is applied to the article, the article should withstand an exposure of at least 18,700 kJ/m² at 340 nm before the b* value obtained using the CIE L*a*b* space increases by 5 or less, 4 or less, 3 or less, or 2 or less before the onset of significant cracking, peeling, delamination or haze.

While the polymeric film substrate useful for practicing the present disclosure has excellent outdoor stability, barrier films are required on at least one side of the polymeric film substrate to reduce the permeation of water vapor to levels that allow its use in long term outdoor applications such as building integrated photovoltaic's (BIPV).

### Barrier Film

Barrier films 120, 320, 420 useful for practicing the present disclosure can be selected from a variety of constructions. Barrier films are typically selected such that they have oxygen and water transmission rates at a specified level as required by the application. In some embodiments, the barrier film has a water vapor transmission rate (WVTR) less than about 0.005 g/m²/day at 38° C. and 100% relative humidity; in some embodiments, less than about 0.0005 g/m²/day at 38° C. and 100% relative humidity; and in some embodiments, less than about 0.00005 g/m²/day at 38° C. and 100% relative humidity. In some embodiments, the flexible barrier film has a WVTR of less than about 0.05, 0.005, 0.0005, or 0.00005 g/m²/day at 50° C. and 100% relative humidity or even less than about 0.005, 0.0005, 0.00005 g/m²/day at 85° C. and 100% relative humidity. In some embodiments, the barrier film has an oxygen transmission rate of less than about 0.005 g/m²/day at 23° C. and 90% relative humidity; in some embodiments, less than about 0.0005 g/m²/day at 23° C. and 90% relative humidity; and in some embodiments, less than about 0.00005 g/m²/day at 23° C. and 90% relative humidity.

Exemplary useful barrier films include inorganic films prepared by atomic layer deposition, thermal evaporation, sputtering, and chemical vapor deposition. Useful barrier films are typically flexible and transparent.

In some embodiments, useful barrier films comprise inorganic/organic multilayers (e.g., 228, 226, 224). Flexible ultra-barrier films comprising inorganic/organic multilayers are described, for example, in U.S. Pat. No. 7,018,713 (Padiyath et al.). Such flexible ultra-barrier films may have a first polymer layer 228 disposed on polymeric film substrate 230 that is overcoated with two or more inorganic barrier layers 226 separated by at least one second polymer layer 224. In some embodiments, the barrier film comprises one inorganic barrier layer 226 interposed between the first polymer layer 228 disposed on the polymeric film substrate 230 and a second polymer layer 224.

The first and second polymer layers 228 and 224 can independently be formed by applying a layer of a monomer or oligomer and crosslinking the layer to form the polymer in situ, for example, by flash evaporation and vapor deposition of a radiation-crosslinkable monomer followed by crosslinking, for example, using an electron beam apparatus, UV light source, electrical discharge apparatus or other suitable device. The first polymer layer 228 is applied to the polymeric film substrate 230, and the second polymer layer is typically applied to the inorganic barrier layer. The materials and methods useful for forming the first and second polymer layers may be independently selected to be the same or different. Useful techniques for flash evaporation and vapor deposition followed by crosslinking in situ can be found, for example, in U.S. Pat. Nos. 4,696,719 (Bischoff), 4,722,515 (Ham), 4,842,893 (Yializis et al.), 4,954,371 (Yializis), 5,018,048 (Shaw et al.), 5,032,461 (Shaw et al.), 5,097,800 (Shaw et al.), 5,125,138 (Shaw et al.), 5,440,446 (Shaw et al.), 5,547,908 (Furuzawa et al.), 6,045,864 (Lyons et al.), 6,231,939 (Shaw et al.) and 6,214,422 (Yializis); in published PCT Application No. WO 00/26973 (Delta V Technologies, Inc.); in D. G. Shaw and M. G. Langlois, “A New Vapor Deposition Process for Coating Paper and Polymer Webs”, 6th International Vacuum Coating Conference (1992); in D. G. Shaw and M. G. Langlois, “A New High Speed Process for Vapor Depositing Acrylate Thin Films: An Update”, Society of Vacuum Coaters 36th Annual Technical Conference Proceedings (1993); in D. G. Shaw and M. G. Langlois, “Use of Vapor Deposited Acrylate Coatings to Improve the Barrier Properties of Metallized Film”, Society of Vacuum Coaters 37th Annual Technical Conference Proceedings (1994); in D. G. Shaw, M. Roehrig, M. G. Langlois and C. Sheehan, “Use of Evaporated Acrylate Coatings to Smooth the Surface of Polyester and Polypropylene Film Substrates”, RadTech (1996); in J. Affinito, P. Martin, M. Gross, C. Coronado and E. Greenwell, “Vacuum deposited polymer/metal multilayer films for optical application”, Thin Solid Films 270, 43-48 (1995); and in J. D. Affinito, M. E. Gross, C. A. Coronado, G. L. Graff, E. N. Greenwell and P. M. Martin, “Polymer-Oxide Transparent Barrier Layers”, Society of Vacuum Coaters 39th Annual Technical Conference Proceedings (1996). In some embodiments, the polymer layers and inorganic barrier layer are sequentially deposited in a single pass vacuum coating operation with no interruption to the coating process.

The coating efficiency of the first polymer layer 228 can be improved, for example, by cooling the polymeric film substrate 230. Similar techniques can also be used to improve the coating efficiency of the second polymer layer 224. The monomer or oligomer useful for forming the first and/or second polymer layers can also be applied using conventional coating methods such as roll coating (e.g., gravure roll coating) or spray coating (e.g., example, electrostatic spray coating). The first and/second polymer layers can also be formed by applying a layer containing an oligomer or polymer in solvent and then removing the solvent using conventional techniques (e.g., at least one of heat or vacuum). Plasma polymerization may also be employed.

Volatilizable acrylate and methacrylate monomers are useful for forming the first and second polymer layers. In some embodiments, volatilizable acrylates are used. Volatilizable acrylate and methacrylate monomers may have a molecular weight in the range from about 150 to about 600 grams per mole, or, in some embodiments, from about 200 to about 400 grams per mole. In some embodiments, volatilizable acrylate and methacrylate monomers have a value of the ratio of the molecular weight to the number of (meth)acrylate functional groups per molecule in the range from about 150 to about 600 g/mole/(meth)acrylate group, in some embodiments, from about 200 to about 400 g/mole/(meth)acrylate group. Fluorinated acrylates and methacrylates can be used at higher molecular weight ranges or ratios, for example, about 400 to about 3000 molecular weight or about 400 to about 3000 g/mole/(meth)acrylate group. Exemplary useful volatilizable acrylates and methacrylates include hexanediol diacrylate, ethoxyethyl acrylate, phenoxyethyl acrylate, cyanoethyl(mono)acrylate, isobornyl acrylate, isobornyl methacrylate, octadecyl acrylate, isodecyl acrylate, lauryl acrylate, beta-carboxyethyl acrylate, tetrahydrofurfuryl acrylate, dinitrile acrylate, pentafluorophenyl acrylate, nitrophenyl acrylate, 2-phenoxyethyl acrylate, 2-phenoxyethyl methacrylate, 2,2,2-trifluoromethyl(meth)acrylate, diethylene glycol diacrylate, triethylene glycol diacrylate, triethylene glycol dimethacrylate, tripropylene glycol diacrylate, tetraethylene glycol diacrylate, neopentyl glycol diacrylate, propoxylated neopentyl glycol diacrylate, polyethylene glycol diacrylate, tetraethylene glycol diacrylate, bisphenol A epoxy diacrylate, 1,6-hexanediol dimethacrylate, trimethylol propane triacrylate, ethoxylated trimethylol propane triacrylate, propoxylated trimethylol propane triacrylate, tris(2-hydroxyethyl)isocyanurate triacrylate, pentaerythritol triacrylate, phenylthioethyl acrylate, naphthyloxyethyl acrylate, cyclic diacrylates (for example, EB-130 from Cytec Industries Inc. and tricyclodecane dimethanol diacrylate, available as SR833S from Sartomer Co.), epoxy acrylate RDX80095 from Cytec Industries Inc., and mixtures thereof.

Useful monomers for forming the first and second polymer layers are available from a variety of commercial sources and include urethane acrylates (e.g., available from Sartomer Co., Exton, Pa. under the trade designations “CN-968” and “CN-983”), isobornyl acrylate (e.g., available from Sartomer Co. under the trade designation “SR-506”), dipentaerythritol pentaacrylates (e.g., available from Sartomer Co. under the trade designation “SR-399”), epoxy acrylates blended with styrene (e.g., available from Sartomer Co. under the trade designation “CN-120S80”), di-trimethylolpropane tetraacrylates (e.g., available from Sartomer Co. under the trade designation “SR-355”), diethylene glycol diacrylates (e.g., available from Sartomer Co. under the trade designation “SR-230”), 1,3-butylene glycol diacrylate (e.g., available from Sartomer Co. under the trade designation “SR-212”), pentaacrylate esters (e.g., available from Sartomer Co. under the trade designation “SR-9041”), pentaerythritol tetraacrylates (e.g., available from Sartomer Co. under the trade designation “SR-295”), pentaerythritol triacrylates (e.g., available from Sartomer Co. under the trade designation “SR-444”), ethoxylated (3) trimethylolpropane triacrylates (e.g., available from Sartomer Co. under the trade designation “SR-454”), ethoxylated (3) trimethylolpropane triacrylates (e.g., available from Sartomer Co. under the trade designation “SR-454HP”), alkoxylated trifunctional acrylate esters (e.g., available from Sartomer Co. under the trade designation “SR-9008”), dipropylene glycol diacrylates (e.g., available from Sartomer Co. under the trade designation “SR-508”), neopentyl glycol diacrylates (e.g., available from Sartomer Co. under the trade designation “SR-247”), ethoxylated (4) bisphenol a dimethacrylates (e.g., available from Sartomer Co. under the trade designation “CD-450”), cyclohexane dimethanol diacrylate esters (e.g., available from Sartomer Co. under the trade designation “CD-406”), isobornyl methacrylate (e.g., available from Sartomer Co. under the trade designation “SR-423”), cyclic diacrylates (e.g., available from UCB Chemical, Smyrna, Ga., under the trade designation “IRR-214”) and tris (2-hydroxy ethyl) isocyanurate triacrylate (e.g., available from Sartomer Co. under the trade designation “SR-368”), acrylates of the foregoing methacrylates and methacrylates of the foregoing acrylates.

Other monomers that are useful for forming the first and/or second polymer layers include vinyl ethers, vinyl naphthylene, acrylonitrile, and mixtures thereof.

The desired chemical composition and thickness of the first polymer layer 228 will depend in part on the nature and surface topography of the polymeric film substrate 230. The thickness of the first and/or second polymer layers will typically be sufficient to provide a smooth, defect-free surface to which inorganic barrier layer 226 can be applied subsequently. For example, the first polymer layer may have a thickness of a few nm (for example, 2 or 3 nm) to about 5 micrometers or more. The thickness of the second polymer layer may also be in this range and may, in some embodiments, be thinner than the first polymer layer.

Inorganic barrier layer 226 can be formed from a variety of materials. Useful materials include metals, metal oxides, metal nitrides, metal carbides, metal oxynitrides, metal oxyborides, and combinations thereof. Exemplary metal oxides include silicon oxides such as silica, aluminum oxides such as alumina, titanium oxides such as titania, indium oxides, tin oxides, indium tin oxide (ITO), tantalum oxide, zirconium oxide, niobium oxide, and combinations thereof. Other exemplary materials include boron carbide, tungsten carbide, silicon carbide, aluminum nitride, silicon nitride, boron nitride, aluminum oxynitride, silicon oxynitride, boron oxynitride, zirconium oxyboride, titanium oxyboride, and combinations thereof. In some embodiments, the inorganic barrier layer comprises at least one of ITO, silicon oxide, or aluminum oxide. In some embodiments, with the proper selection of the relative proportions of each elemental constituent, ITO can be electrically conductive. The inorganic barrier layers can be formed, for example, using techniques employed in the film metallizing art such as sputtering (for example, cathode or planar magnetron sputtering, dual AC planar magnetron sputtering or dual AC rotatable magnetron sputtering), evaporation (for example, resistive or electron beam evaporation and energy enhanced analogs of resistive or electron beam evaporation including ion beam and plasma assisted deposition), chemical vapor deposition, plasma-enhanced chemical vapor deposition, and plating. In some embodiments, the inorganic barrier layers are formed using sputtering, for example, reactive sputtering. Enhanced barrier properties may be observed when the inorganic layer is formed by a high energy deposition technique such as sputtering compared to lower energy techniques such as conventional vapor deposition processes. Without being bound by theory, it is believed that the enhanced properties are due to the condensing species arriving at the substrate with greater kinetic energy, leading to a lower void fraction as a result of compaction.

The desired chemical composition and thickness of each inorganic barrier layer will depend in part on the nature and surface topography of the underlying layer and on the desired optical properties for the barrier film. The inorganic barrier layers typically are sufficiently thick so as to be continuous, and sufficiently thin so as to ensure that the barrier films and assemblies disclosed herein will have the desired degree of visible light transmission and flexibility. The physical thickness (as opposed to the optical thickness) of each inorganic barrier layer may be, for example, about 3 nm to about 150 nm (in some embodiments, about 4 nm to about 75 nm). The inorganic barrier layer typically has an average transmission over the visible portion of the spectrum of at least about 75% (in some embodiments at least about 80, 85, 90, 92, 95, 97, or 98%) measured along the normal axis. In some embodiments, the inorganic barrier layer has an average transmission over a range of 400 nm to 1400 nm of at least about 75% (in some embodiments at least about 80, 85, 90, 92, 95, 97, or 98%). Useful inorganic barrier layers typically are those that do not interfere with absorption of visible or infrared light, for example, by photovoltaic cells.

Additional inorganic barrier layers and polymer layers can be present if desired. In embodiments wherein more than one inorganic barrier layer is present, the inorganic barrier layers do not have to be the same or have the same thickness. When more than one inorganic barrier layer is present, the inorganic barrier layers can respectively be referred to as the “first inorganic barrier layer” and “second inorganic barrier layer”. Additional “polymer layers” may be present in between additional inorganic barrier layers. For example, the barrier film may have several alternating inorganic barrier layers and polymer layers. Each unit of inorganic barrier layer combined with a polymer layer is referred to as a dyad, and the barrier film can include any number of dyads. It can also include various types of optional layers between the dyads.

Surface treatments or tie layers can be applied between any of the polymer layers or inorganic barrier layers, for example, to improve smoothness or adhesion. Useful surface treatments include electrical discharge in the presence of a suitable reactive or non-reactive atmosphere (e.g., plasma, glow discharge, corona discharge, dielectric barrier discharge or atmospheric pressure discharge); chemical pretreatment; or flame pretreatment. A separate adhesion promotion layer may also be formed between the major surface of the polymeric film substrate and the barrier film. The adhesion promotion layer can be, for example, a separate polymeric layer or a metal-containing layer such as a layer of metal, metal oxide, metal nitride or metal oxynitride. The adhesion promotion layer may have a thickness of a few nanometers (nm) (e.g., 1 or 2 nm) to about 50 nm or more.

In some embodiments, useful barrier films comprise plasma deposited polymer layers (for example, diamond-like layers) such as those disclosed in U.S. Pat. App. Pub. No. 2007-0020451 (Padiyath et al.). For example, barrier films can be made by overcoating a first polymer layer on the polymeric film substrate, and a plasma deposited polymer layer overcoated on the first polymer layer. The first polymer layer may be as described in any of the above embodiments of the first polymer layer. The plasma deposited polymer layer may be, for example, a diamond-like carbon layer or a diamond-like glass. The term “overcoated” to describe the position of a layer with respect to a substrate or other element of a barrier film, refers to the layer as being atop the substrate or other element, but not necessarily contiguous to either the substrate or the other element. The term “diamond-like glass” (DLG) refers to substantially or completely amorphous glass including carbon and silicon, and optionally including one or more additional components selected from the group including hydrogen, nitrogen, oxygen, fluorine, sulfur, titanium, and copper. Other elements may be present in certain embodiments. The amorphous diamond-like glass films may contain clustering of atoms to give it a short-range order but are essentially devoid of medium and long range ordering that lead to micro or macro crystallinity, which can adversely scatter radiation having wavelengths of from 180 nm to 800 nm. The term “diamond-like carbon” (DLC) refers to an amorphous film or coating comprising approximately 50 to 90 atomic percent carbon and approximately 10 to 50 atomic percent hydrogen, with a gram atom density of between approximately 0.20 and approximately 0.28 gram atoms per cubic centimeter, and composed of approximately 50% to approximately 90% tetrahedral bonds.

In some embodiments, the barrier film can have multiple layers made from alternating DLG or DLC layers and polymer layers (e.g., first and second polymer layers as described above) overcoated on the polymeric film substrate. Each unit including a combination of a polymer layer and a DLG or DLC layer is referred to as a dyad, and the assembly can include any number of dyads. It can also include various types of optional layers between the dyads. Adding more layers in the barrier film may increase its imperviousness to oxygen, moisture, or other contaminants and may also help cover or encapsulate defects within the layers.

In some embodiments, the diamond-like glass comprises, on a hydrogen-free basis, at least 30% carbon, a substantial amount of silicon (typically at least 25%) and no more than 45% oxygen. The unique combination of a fairly high amount of silicon with a significant amount of oxygen and a substantial amount of carbon makes these films highly transparent and flexible. Diamond-like glass thin films may have a variety of light transmissive properties. Depending upon the composition, the thin films may have increased transmissive properties at various frequencies. However, in some embodiments, the thin film (when approximately one micron thick) is at least 70% transmissive to radiation at substantially all wavelengths from about 250 nm to about 800 nm (e.g., 400 nm to about 800 nm). A transmission of 70% for a one micron thick film corresponds to an extinction coefficient (k) of less than 0.02 in the visible wavelength range between 400 nm and 800 nm.

In creating a diamond-like glass film, various additional components can be incorporated to alter and enhance the properties that the diamond-like glass film imparts to the substrate (for example, barrier and surface properties). The additional components may include one or more of hydrogen, nitrogen, fluorine, sulfur, titanium, or copper. Other additional components may also be of benefit. The addition of hydrogen promotes the formation of tetrahedral bonds. The addition of fluorine may enhance barrier and surface properties of the diamond-like glass film, including the ability to be dispersed in an incompatible matrix. Sources of fluorine include compounds such as carbon tetrafluoride (CF₄), sulfur hexafluoride (SF₆), C₂F₆, C₃F₈, and C₄F₁₀. The addition of nitrogen may be used to enhance resistance to oxidation and to increase electrical conductivity. Sources of nitrogen include nitrogen gas (N₂), ammonia (NH₃), and hydrazine (N₂H₆). The addition of sulfur can enhance adhesion. The addition of titanium tends to enhance adhesion and diffusion and barrier properties.

Various additives to the DLC film can be used. In addition to nitrogen or fluorine, which may be added for the reasons described above with regard to diamond-like glass, oxygen and silicon may be added. The addition of silicon and oxygen to the DLC coating tend to improve the optical transparency and thermal stability of the coating. Sources of oxygen include oxygen gas (O₂), water vapor, ethanol, and hydrogen peroxide. Sources of silicon preferably include silanes such as SiH₄, Si₂H₆, and hexamethyldisiloxane.

Additives to DLG or DLC films described above may be incorporated into the diamond-like matrix or attached to the surface atomic layer. If the additives are incorporated into the diamond-like matrix they may cause perturbations in the density and/or structure, but the resulting material is essentially a densely packed network with diamond-like carbon characteristics (e.g., chemical inertness, hardness, and barrier properties). If the additive concentration is too large (e.g., greater than 50 atomic percent relative to the carbon concentration) the density will be affected and the beneficial properties of the diamond-like carbon network will be lost. If the additives are attached to the surface atomic layers they will alter only the surface structure and properties. The bulk properties of the diamond-like carbon network will be preserved.

Plasma deposited polymers such as diamond-like glass and diamond-like carbon can be synthesized from a plasma by using precursor monomers in the gas phase at low temperatures. Precursor molecules are broken down by energetic electrons present in the plasma to form free radical species. These free radical species react at the substrate surface and lead to polymeric thin film growth. Due to the non-specificity of the reaction processes in both the gas phase and the substrate, the resulting polymer films are typically highly cross-linked and amorphous in nature. For additional information regarding plasma deposited polymers, see, for example, H. Yasuda, “Plasma Polymerization,” Academic Press Inc., New York (1985); R.d'Agostino (Ed), “Plasma Deposition, Treatment & Etching of Polymers,” Academic Press, New York (1990); and H. Biederman and Y. Osada, “Plasma Polymerization Processes,” Elsever, N.Y. (1992).

Typically, plasma deposited polymer layers described herein have an organic nature due to the presence of hydrocarbon and carbonaceous functional groups such as CH₃, CH₂, CH, Si—C, Si—CH₃, Al—C, Si—O—CH₃, etc. The plasma deposited polymer layers are substantially sub-stoichiometric in their inorganic component and substantially carbon-rich. In films containing silicon, for example, the oxygen to silicon ratio is typically below 1.8 (silicon dioxide has a ratio of 2.0), more typically below 1.5 for DLG, and the carbon content is at least about 10%. In some embodiments, the carbon content is at least about 20% or 25%.

Amorphous diamond-like films formed via ion enhanced plasma chemical vapor deposition (PECVD) utilizing silicone oil and an optional silane source to form the plasma as described, for example, in U.S. Pat. App. Pub. No. 2008-0196664 (David et al.), can also be useful in barrier films. The terms “silicone”, “silicone oil”, or “siloxanes” are used interchangeably and refer to oligomeric and higher molecular weight molecules having a structural unit R₂SiO in which R is independently selected from hydrogen, (C₁-C₈)alkyl, (C₅-C₁₈)aryl, (C₆-C₂₆)arylalkyl, or (C₆-C₂₆)alkylaryl. These can also be referred to as polyorganosiloxanes and include chains of alternating silicon and oxygen atoms (—O—Si—O—Si—O—) with the free valences of the silicon atoms joined usually to R groups, but may also be joined (crosslinked) to oxygen atoms and silicon atoms of a second chain, forming an extended network (high MW). In some embodiments, a siloxane source such as vaporized silicone oil is introduced in quantities such that the resulting plasma formed coatings are flexible and have high optical transmission. Any additional useful process gases, such as oxygen, nitrogen and/or ammonia, for example, can be used with the siloxane and optional silane to assist in maintaining the plasma and to modify the properties of the amorphous diamond-like film layers.

In some embodiments, combinations of two or more different plasma deposited polymers can be used. For example, different plasma deposited polymer layers formed by changing or pulsing the process gases that form the plasma for depositing the polymer layer. In another example, a first layer of a first amorphous diamond-like film can be formed and then a second layer of a second amorphous diamond-like film can be formed on the first layer, where the first layer has a different composition than the second layer. In some embodiments, a first amorphous diamond-like film layer is formed from a silicone oil plasma and then a second amorphous diamond-like film layer is formed from a silicone oil and silane plasma. In other embodiments, two or more amorphous diamond-like films layers of alternating composition are formed to create the amorphous diamond-like film.

Plasma deposited polymers such as diamond-like glass and diamond-like carbon can be any useful thickness. In some embodiments, the plasma deposited polymer can have a thickness of at least 500 Angstroms, or at least 1,000 Angstroms. In some embodiments, the plasma deposited polymer can have a thickness in a range from 1,000 to 50,000 Angstroms, from 1,000 to 25,000 Angstroms, or from 1,000 to 10,000 Angstroms.

Other plasma deposition processes for preparing useful barrier films 120 such as carbon-rich films, silicon-containing films, or combinations thereof are disclosed, for example, in U.S. Pat. No. 6,348,237 (Kohler et al.). Carbon-rich films may contain at least 50 atom percent carbon, and typically about 70-95 atom percent carbon, 0.1-20 atom percent nitrogen, 0.1-15 atom percent oxygen, and 0.1-40 atom percent hydrogen. Such carbon-rich films can be classified as “amorphous”, “hydrogenated amorphous”, “graphitic”, “i-carbon”, or “diamond-like”, depending on their physical and chemical properties. Silicon-containing films are usually polymeric and contain in random composition silicon, carbon, hydrogen, oxygen, and nitrogen.

Carbon-rich films and silicon-containing films can be formed by means of plasma interaction with a vaporized organic material, which is normally a liquid at ambient temperature and pressure. The vaporized organic material is typically capable of condensing in a vacuum of less than about 1 Torr (130 Pa). The vapors are directed toward the polymeric film substrate in a vacuum (e.g., in a conventional vacuum chamber) at a negatively charged electrode as described above for plasma polymer deposition. A plasma (for example, an argon plasma or a carbon-rich plasma as described in U.S. Pat. No. 5,464,667 (Kohler et al.)) and at least one vaporized organic material are allowed to interact during formation of a film. The plasma is one that is capable of activating the vaporized organic material. The plasma and vaporized organic material can interact either on the surface of the substrate or before contacting the surface of the substrate. Either way, the interaction of the vaporized organic material and the plasma provides a reactive form of the organic material (for example, loss of methyl group from silicone) to enable densification of the material upon formation of the film, as a result of polymerization and/or crosslinking, for example. Significantly, the films are prepared without the need for solvents.

The formed films can be uniform multi-component films (for example, one layer coatings produced from multiple starting materials), uniform one-component films, and/or multilayer films (for example, alternating layers of carbon-rich material and silicone materials). For example, using a carbon-rich plasma in one stream from a first source and a vaporized high molecular weight organic liquid such as dimethylsiloxane oil in another stream from a second source, a one-pass deposition procedure may result in a multilayer construction of the film (e.g., a layer of a carbon-rich material, a layer of dimethylsiloxane that is at least partially polymerized, and an intermediate or interfacial layer of a carbon/dimethylsiloxane composite). Variations in system arrangements result in the controlled formation of uniform multi-component films or layered films with gradual or abrupt changes in properties and composition as desired. Uniform coatings of one material can also be formed from a carrier gas plasma, such as argon, and a vaporized high molecular weight organic liquid, such as dimethylsiloxane oil.

Other useful barrier films 120 comprise films having a graded-composition barrier coating such as those described in U.S. Pat. No. 7,015,640 (Schaepkens et al.). Films having a graded-composition barrier coating can be made by depositing reaction or recombination products of reacting species onto polymeric film substrate 130. Varying the relative supply rates or changing the identities of the reacting species results in a coating that has a graded composition across its thickness. Suitable coating compositions are organic, inorganic, or ceramic materials. These materials are typically reaction or recombination products of reacting plasma species and are deposited onto the substrate surface. Organic coating materials typically comprise carbon, hydrogen, oxygen, and optionally other minor elements, such as sulfur, nitrogen, silicon, etc., depending on the types of reactants. Suitable reactants that result in organic compositions in the coating are straight or branched alkanes, alkenes, alkynes, alcohols, aldehydes, ethers, alkylene oxides, aromatics, etc., having up to 15 carbon atoms. Inorganic and ceramic coating materials typically comprise oxide; nitride; carbide; boride; or combinations thereof of elements of Groups IIA, IIIA, IVA, VA, VIA, VIIA, IB, and IIB; metals of Groups IIIB, IVB, and VB; and rare-earth metals. For example, silicon carbide can be deposited onto a substrate by recombination of plasmas generated from silane (SiH₄) and an organic material, such as methane or xylene. Silicon oxycarbide can be deposited from plasmas generated from silane, methane, and oxygen or silane and propylene oxide. Silicon oxycarbide also can be deposited from plasmas generated from organosilicone precursors, such as tetraethoxysilane (TEOS), hexamethyldisiloxane (HMDSO), hexamethyldisilazane (HMDSN), or octamethylcyclotetrasiloxane (D4). Silicon nitride can be deposited from plasmas generated from silane and ammonia. Aluminum oxycarbonitride can be deposited from a plasma generated from a mixture of aluminum tartrate and ammonia. Other combinations of reactants may be chosen to obtain a desired coating composition. The choice of the particular reactants is within the skills of the artisans. A graded composition of the coating can be obtained by changing the compositions of the reactants fed into the reactor chamber during the deposition of reaction products to form the coating or by using overlapping deposition zones, for example, in a web process. The coating may be formed by one of many deposition techniques, such as plasma-enhanced chemical-vapor deposition (PECVD), radio-frequency plasma-enhanced chemical-vapor deposition (RFPECVD), expanding thermal-plasma chemical-vapor deposition (ETPCVD), sputtering including reactive sputtering, electron-cyclotron-resonance plasma-enhanced chemical-vapor deposition (ECRPECVD), inductively coupled plasma-enhanced chemical-vapor deposition (ICPECVD), or combinations thereof. Coating thickness is typically in the range from about 10 nm to about 10000 nm, in some embodiments from about 10 nm to about 1000 nm, and in some embodiments from about 10 nm to about 200 nm. The barrier film can have an average transmission over the visible portion of the spectrum of at least about 75% (in some embodiments at least about 80, 85, 90, 92, 95, 97, or 98%) measured along the normal axis. In some embodiments, the barrier film has an average transmission over a range of 400 nm to 1400 nm of at least about 75% (in some embodiments at least about 80, 85, 90, 92, 95, 97, or 98%).

Other suitable barrier films include thin and flexible glass laminated on a polymer film, and glass deposited on a polymeric film.

### Adhesive

PSAs are well known to those of ordinary skill in the art to possess properties including the following: (1) aggressive and permanent tack, (2) adherence with no more than finger pressure, (3) sufficient ability to hold onto an adherend, and (4) sufficient cohesive strength to be cleanly removable from the adherend. Materials that have been found to function well as PSAs are polymers designed and formulated to exhibit the requisite viscoelastic properties resulting in a desired balance of tack, peel adhesion, and shear holding power.

The PSA layer disclosed herein is at least 0.25 mm (in some embodiments, at least 0.28, 0.30, 0.33, 0.35, or 0.38 mm) in thickness. In some embodiments, the PSA layer has a thickness up to about 0.5 mm (in some embodiments, up to 0.51, 0.53, 0.56, 0.58, 0.61, or 0.64 mm) in thickness. For example, the thickness of the PSA layer may be in a range from 0.25 mm to 0.64 mm, 0.30 mm to 0.60 mm, or 0.33 to 0.5 mm. In some embodiments, the PSA has opposing major surfaces (e.g., third and fourth major surfaces) wherein one of the major surfaces is in intimate contact with the barrier film on a side opposite the polymeric film substrate.

PSAs useful for practicing the present disclosure typically do not flow and have sufficient barrier properties to provide slow or minimal infiltration of oxygen and moisture through the adhesive bond line. Also, the PSAs disclosed herein are generally transmissive to visible and infrared light such that they do not interfere with absorption of visible light, for example, by photovoltaic cells. The PSAs may have an average transmission over the visible portion of the spectrum of at least about 75% (in some embodiments at least about 80, 85, 90, 92, 95, 97, or 98%) measured along the normal axis. In some embodiments, the PSA has an average transmission over a range of 400 nm to 1400 nm of at least about 75% (in some embodiments at least about 80, 85, 90, 92, 95, 97, or 98%). Exemplary PSAs include acrylates, silicones, polyisobutylenes, ureas, and combinations thereof. Some useful commercially available PSAs include UV curable PSAs such as those available from Adhesive Research, Inc., Glen Rock, Pa., under the trade designations “ARclear 90453” and “ARclear 90537” and optically clear PSAs available, for example, from 3M Company, St. Paul, Minn., under the trade designations “OPTICALLY CLEAR LAMINATING ADHESIVE 8141” and “OPTICALLY CLEAR LAMINATING ADHESIVE 8171”.

In some embodiments, PSAs according to and/or useful for practicing the present disclosure have a glass transition temperature up to 0° C. The glass transition temperature can be measured, for example, by differential scanning calorimetry (DSC) using techniques known in the art. In some embodiments, the glass transition temperature is less than 0° C. (in some embodiments, up to −5, −10, −15, or −20° C.). For example, the glass transition temperature of the PSA may be in a range from −65° C. to 0° C., −60° C. to 0° C., −60° C. to −5° C., −60 to −10° C., or −40 to −20° C., as measured by DSC. A glass transition temperature up to 0° C. may improve the durability of the assembly according to the present disclosure, for example, during thermal cycling (e.g., from −40 to 80° C.).

In some embodiments, PSAs according to and/or useful for practicing the present disclosure are free of solvent (e.g., free of added solvent). Typically, free of solvent means that the PSAs are formed by a solventless process (that is, no solvent is added during the process of making the PSA).

In some embodiments, PSAs according to and/or useful for practicing the present disclosure comprise polyisobutylene. The polyisobutylene may have a polyisobutylene skeleton in the main or a side chain. Useful polyisobutylenes can be prepared, for example, by polymerizing isobutylene alone or in combination with n-butene, isoprene, or butadiene in the presence of a Lewis acid catalyst (for example, aluminum chloride or boron trifluoride).

Useful polyisobutylene materials are commercially available from several manufacturers. Homopolymers are commercially available, for example, under the trade designation “OPPANOL” (e.g., “OPPANOL B15”, “B30”, “B50”, “B100”, “B150”, and “B200”) from BASF Corp. (Florham Park, N.J.). These polymers often have a weight average molecular weight in the range of about 40,000 to 4,000,000 grams/mole. Still other exemplary homopolymers are commercially available from United Chemical Products (UCP) of St. Petersburg, Russia in a wide range of molecular weights. For example, homopolymers commercially available from UCP under the trade designation “SDG” have a viscosity average molecular weight in the range of about 35,000 to 65,000 grams/mole. Homopolymers commercially available from UCP under the trade designation “EFROLEN” have a viscosity average molecular weight in the range of about 480,000 to about 4,000,000 grams/mole. Homopolymers commercially available from UCP under the trade designation “JHY” have a viscosity average molecular weight in the range of about 3000 to about 55,000 grams/mole. These homopolymers typically do not have reactive double bonds.

Other suitable polyisobutylene homopolymers are commercially available under the trade designation “GLISSOPAL” (e.g., “GLISSOPAL 1000”, “1300”, and “2300”) from BASF Corp. These polyisobutylene materials usually have terminal double bonds and are considered to be reactive polyisobutylene materials. These polymers often have a number average molecular weight in the range of about 500 to about 2,300 grams/mole. The ratio of the weight average molecular weight to the number average molecular weight is typically in the range of about 1.6 to 2.0.

Polyisobutylene copolymers are often prepared by polymerizing isobutylene in the presence of a small amount of another monomer such as, for example, styrene, isoprene, butene, or butadiene. These copolymers are typically prepared from a monomer mixture that includes at least 70 weight percent, at least 75 weight percent, at least 80 weight percent, at least 85 weight percent, at least 90 weight percent, or at least 95 weight percent isobutylene based on the weight of monomers in the monomer mixture. Suitable isobutylene/isoprene copolymers are commercially available under the trade designation “EXXON BUTYL” (e.g., “EXXON BUTYL 065”, “068”, and “268”) from Exxon Mobil Corp., Irving, Tex. These materials have unsaturation in the range of about 1.05 to about 2.30 mole percent. Other exemplary isobutylene/isoprene copolymers are commercially available from United Chemical Products such as BK-1675N with an unsaturation of about 1.7 mole percent. Still other exemplary isobutylene/isoprene copolymers are commercially available from “LANXESS” (Sarnia, Ontario, Canada) such as “LANXESS BUTYL 301” with an unsaturation of about 1.85 mole percent, “LANXESS BUTYL 101-3” with an unsaturation of about 1.75 mole percent, and “LANXESS BUTYL 402” with an unsaturation of about 2.25 weight percent. Suitable isobutylene/styrene block copolymers are commercially available under the trade designation “SIBSTAR” from Kaneka (Osaka, Japan). These materials are available as both diblocks and triblocks with the styrene content varying from about 15 to 30 weight percent based on the weight of the copolymer. Other suitable polyisobutylene resins are commercially available, for example, from Exxon Chemical Co. under the trade designation “VISTANEX”, from Goodrich Corp., Charlotte, N.C., under the trade designation “HYCAR”, and from Japan Butyl Co., Ltd., Kanto, Japan, under the trade designation “JSR BUTYL”.

A polyisobutylene useful for practicing the present disclosure may have a wide variety of molecular weights and a wide variety of viscosities. In some embodiments, the polyisobutylene has a weight average molecular weight (as measured by Gel Permeation Chromatography using polystyrene standards) of at least about 300,000 grams per mole or more (in some embodiments, at least about 400,000, 500,000 grams per mole or more). In some embodiments, the polyisobutylene has a weight average molecular weight of less than 300,000 (in some embodiments, up to 280,000, 275,000, 270,000, 260,000, 250,000, 240,000, 230,000, 220,000, 210,000, or 200,000) grams per mole. In some embodiments, when defined by the viscosity as measured by intrinsic viscosity at 20° C. in diisobutylene, the polyisobutylene has a viscosity average molecular weight of about 100,000 to 10,000,000 grams per mole or about 500,000 to 5,000,000 grams per mole. Polyisobutylenes of many different molecular weights and viscosities are commercially available. In some embodiments, the molecular weight of the polyisobutylene changes during the process of making the PSA as described below.

In some embodiments of PSAs comprising polyisobutylene, the PSA further comprises a hydrogenated hydrocarbon tackifier (in some embodiments, a poly(cyclic olefin)). In some of these embodiments, about 5 to 90 percent by weight the hydrogenated hydrocarbon tackifier (in some embodiments, the poly(cyclic olefin)) is blended with about 10 to 95 percent by weight polyisobutylene, based on the total weight of the PSA composition. In other of these embodiments, the PSA comprises about 5 to 70 weight percent hydrogenated hydrocarbon tackifier (in some embodiments, the poly(cyclic olefin)) and about 30 to 95 weight percent polyisobutylene, based on the total weight of the PSA composition. In yet other of these embodiments, the hydrogenated hydrocarbon tackifier (in some embodiments, the poly(cyclic olefin)) is present in an amount of less than 20 or 15 percent by weight, based on the total weight of the PSA composition. For example, the hydrogenated hydrocarbon tackifier (in some embodiments, the poly(cyclic olefin)) may be present in a range from 5 to 19.95, 5 to 19, 5 to 17, 5 to 15, 5 to 13, or 5 to 10 percent by weight, based on the total weight of the PSA composition. In some embodiments, the PSA is free of acrylic monomers and polyacrylates. Useful polyisobutylene PSAs include adhesive compositions comprising a hydrogenated poly(cyclic olefin) and a polyisobutylene resin such as those disclosed in Int. Pat. App. Pub. No. WO 2007/087281 (Fujita et al.).

The “hydrogenated” hydrocarbon tackifier component may include a partially hydrogenated resin (e.g., having any hydrogenation ratio), a completely hydrogenated resin, or a combination thereof. In some embodiments, the hydrogenated hydrocarbon tackifier is completely hydrogenated, which may lower the moisture permeability of the PSA and improve the compatibility with the polyisobutylene resin. The hydrogenated hydrocarbon tackifiers are often hydrogenated cycloaliphatic resins, hydrogenated aromatic resins, or combinations thereof. For example, some tackifying resins are hydrogenated C9-type petroleum resins obtained by copolymerizing a C9 fraction produced by thermal decomposition of petroleum naphtha, hydrogenated C5-type petroleum resins obtained by copolymerizing a C5 fraction produced by thermal decomposition of petroleum naphtha, or hydrogenated C5/C9-type petroleum resins obtained by polymerizing a combination of a C5 fraction and C9 fraction produced by thermal decomposition of petroleum naphtha. The C9 fraction can include, for example, indene, vinyl-toluene, alpha-methylstyrene, beta-methylstyrene, or a combination thereof. Other exemplary tackifying resins are. The C5 fraction can include, for example, pentane, isoprene, piperine, 1,3-pentadiene, or a combination thereof.

Some suitable hydrogenated hydrocarbon tackifiers are commercially available under the trade designation “ARKON” (e.g., “ARKON P” or “ARKON M”) from Arakawa Chemical Industries Co., Ltd. (Osaka, Japan). These materials are described in the trade literature as being water white, hydrogenated hydrocarbon resins. “ARKON P” hydrogenated hydrocarbons (e.g., P-70, P-90, P-100, P-115, and P-140) are fully hydrogenated while “ARKON M” hydrogenated hydrocarbons (e.g., M-90, M-100, M-115, and M-135) are partially hydrogenated. Hydrogenated hydrocarbon “ARKON P-100” has a number average molecular weight of about 850 grams/mole, a softening point of about 100° C., and a glass transition temperature of about 45° C. Hydrogenated hydrocarbon “ARKON P-140” has a number average molecular weight of about 1250 grams/mole, a softening point of about 140° C., and a glass transition temperature of about 90° C. Hydrogenated hydrocarbon “ARKON M-90” has a number average molecular weight of about 730 grams/mole, a softening point of about 90° C., and a glass transition temperature of about 36° C. Hydrogenated hydrocarbon “ARKON-M-100” has a number average molecular weight of about 810 grams/mole, a softening point of about 100° C., and a glass transition temperature of about 45° C.

Other suitable hydrogenated hydrocarbon tackifiers are commercially available under the trade designation “ESCOREZ” from Exxon Chemical. The “ESCOREZ 5300” (e.g., grades 5300, 5320, 5340, and 5380) series of resins are described in the trade literature as being water white, cycloaliphatic hydrocarbon resins. These materials have a weight average molecular weight in the range of about 370 grams/mole to about 460 grams/mole, a softening point in the range of about 85° C. to about 140° C., and a glass transition temperature in the range of about 35° C. to about 85° C. The “ESCOREZ 5400” (e.g., grades 5400 and 5415) series of resins are described in the trade literature as being very light colored cycloaliphatic hydrocarbon resins. These materials have a weight average molecular weight in the range of about 400 to about 430 grams/mole, a softening point in the range of about 103° C. to 118° C., and a glass transition temperature in the range of about 50° C. to 65° C. The “ESCOREZ 5600” (e.g., grades 5600, 5615, 5637, and 5690) series of resins are described in the trade literature as being very light colored, aromatic modified cycloaliphatic resin. The percent of aromatic hydrogen atoms is in the range of about 6 to 12 weight percent based on the weight of all the hydrogen atoms in the resins. These materials have a weight average molecular weight in the range of 480 grams/mole to 520 grams/mole, a softening point in the range of about 87° C. to about 133° C., and a glass transition temperature in the range of about 40° C. to 78° C. The “ESCOREZ 1300” (e.g., grades 1315, 1310LC, and 1304) series resins are described in the trade literature as being aliphatic resins with a high softening point. Resin “ESCOREZ 1315” has a weight average molecular weight of about 2200 grams/mole, a softening point in the range of 112° C. to 118° C., and a glass transition temperature about 60° C. Resin “ESCOREZ 1310LC” has a light color, a weight average molecular weight of about 1350 grams/mole, a softening point of 95° C., and a glass transition temperature of about 45° C. Resin “ESCOREZ 1304” has a weight average molecular weight of about 1650 grams/mole, a softening point in the range of 97° C. to 103° C., and a glass transition temperature of 50° C.

Still other suitable hydrogenated hydrocarbon tackifiers are commercially available under the trade designation “REGALREZ” (e.g., grades 1085, 1094, 1126, 1139, 3102, and 6108) from Eastman (Kingsport, Tenn.). These resins are described in the trade literature as hydrogenated aromatic pure monomer hydrocarbon resins. They have a weight average molecular weight ranging from 850 grams/mole to 3100 grams/mole, a softening temperature in the range of 87° C. to 141° C., and a glass transition temperature in the range of 34° C. to 84° C. Resin “REGALEZ 1018” can be used in applications that do not generate heat. This tackifying resin has a weight average molecular weight of approximated 350 grams/mole, a softening point of 19° C., and a glass transition temperature of 22° C.

Yet other suitable hydrogenated hydrocarbon tackifiers are commercially available under the trade designation “WINGTACK” (e.g., “WINGTACK 95” and “WINGTACK RWT-7850”) resins from Cray Valley (Exton, Pa.). The trade literature describes these tackifying resins as synthetic resins obtained by cationic polymerization of aliphatic C5 monomers. Resin “WINGTACK 95” is a light yellow solid with a weight average molecular weight of 1700 grams/mole, a softening point of 98° C., and a glass transition temperature of 55° C. Resin “WINGTACK RWT-7850” is a light yellow solid with a weight average molecular weight of 1700 grams/mole, a softening point of 102° C., and a glass transition temperature of 52° C.

Even further suitable hydrogenated hydrocarbon tackifiers are commercially available under the trade designation “PICCOTAC” (e.g., grades 6095-E, 8090-E, 8095, 8595, 9095, and 9105) from Eastman (Kingsport, Tenn.). The trade literature describes these resins as aromatic modified, aliphatic hydrocarbon resin or as aromatic modified C5 resins. Resin “PICCOTACK 6095-E” has a weight average molecular weight of 1700 grams/mole and a softening point of 98° C. Resin “PICCOTACK 8090-E” has a weight average molecular weight of 1900 grams/mole and a softening point of 92° C. Resin “PICCOTACK 8095” has a weight average molecular weight of 2200 grams/mole and a softening point of 95° C. Resin “PICCOTAC 8595” has a weight average molecular weight of 1700 grams/mole and a softening point of 95° C. Resin “PICCOTAC 9095” has a weight average molecular weight of 1900 grams/mole and a softening point of 94° C. Resin “PICCOTAC 9105” has a weight average molecular weight of 3200 grams/mole and a softening point of 105° C.

In some embodiments, the hydrogenated hydrocarbon tackifier is a hydrogenated poly(cyclic olefin) polymer. Poly(cyclic olefin) polymers generally have low moisture permeability and can impact the adhesive properties of the polyisobutylene resin, for example, by functioning as a tackifier. Exemplary hydrogenated poly(cyclic olefin) polymers include hydrogenated petroleum resins; hydrogenated terpene-based resins (for example, resins commercially available under the trade designation “CLEARON”, in grades P, M and K, from Yasuhara Chemical, Hiroshima, Japan); hydrogenated resin or hydrogenated ester-based resins commercially available, for example, under the trade designation “FORAL AX” and “FORAL 105” from Hercules Inc., Wilmington, Del., under the trade designations “PENCEL A”, “ESTERGUM H”, and “SUPER ESTER A” from Arakawa Chemical Industries Co., Ltd., Osaka, Japan; disproportionate resins or disproportionate ester-based resins (for example, resins commercially available under the trade designation “PINECRYSTAL” from Arakawa Chemical Industries Co., Ltd.); a hydrogenated dicyclopentadiene-based resin (for example, a hydrogenated C5-type petroleum resin obtained by copolymerizing a C5 fraction such as pentene, isoprene, or piperine with 1,3-pentadiene produced through thermal decomposition of petroleum naphtha available, for example, from Exxon Chemical Co., Irving, Tex., under the trade designations “ESCOREZ 5300” or “ESCOREZ 5400” and from Eastman Chemical Co., Kingsport, Tenn., under the trade designation “EASTOTAC H”); a partially hydrogenated aromatic modified dicyclopentadiene-based resin commercially available, for example, from Exxon Chemical Co. under the trade designation “ESCOREZ 5600”; a resin resulting from hydrogenation of a C9-type petroleum resin obtained by copolymerizing a C9 fraction such as indene, vinyltoluene and α- or β-methylstyrene produced by thermal decomposition of petroleum naphtha available, for example, from Arakawa Chemical Industries Co., Ltd. under the trade designations “ARCON P” or “ARCON M”; and a resin resulting from hydrogenation of a copolymerized petroleum resin of the above-described C5 fraction and C9 fraction available, for example, from Idemitsu Petrochemical Co., Tokyo, Japan, under the trade designation “IMARV”. In some embodiments, the hydrogenated poly(cyclic olefin) is a hydrogenated poly(dicyclopentadiene), which may provide advantages to the PSA (e.g., low moisture permeability and transparency).

The hydrogenated hydrocarbon tackifier generally has a solubility parameter (SP value), which is an index for characterizing the polarity of a compound, that is similar to that of the polyisobutylene and exhibits good compatibility (i.e., miscibility) with the polyisobutylene so that a transparent film can be formed. The tackifying resins are typically amorphous and have a weight average molecular weight no greater than 5000 grams/mole. If the weight average molecular weight is greater than about 5000 grams/mole, compatibility with the polyisobutylene material may decrease, tackiness may decrease, or both. The molecular weight is often no greater than 4000 grams/mole, no greater than about 2500 grams/mole, no greater than 2000 grams/mole, no greater than 1500 grams/mole, no greater than 1000 grams/mole, or no greater than 500 grams/mole. In some embodiments, the molecular weight is in the range of 200 to 5000 gram/mole, in the range of 200 to 4000 grams/mole, in the range of 200 to 2000 grams/mole, or in the range of 200 to 1000 gram/mole.

PSA layers according to and/or useful for practicing the present disclosure may be prepared, for example, by solventless extrusion of an extrudable composition comprising the components of the PSA composition. Advantageously, the PSA layer can be made by this process in the absence of solvents, that is, no volatile organic compounds need to be added in the process. In some embodiments, the extrudable composition is extruded onto a release liner. In some embodiments, the extrudable composition is extruded between two release liners. In some embodiments, the extrudable composition is at least partially extruded under vacuum. The extrudable composition may comprise, for example, a polyisobutylene and a hydrogenated hydrocarbon tackifier (in some embodiments, a poly(cyclic olefin)). In some embodiments, the PSA layer disclosed herein is made by extruding in a solventless extrusion process an extrudable composition comprising polyisobutylene having a weight average molecular weight of at least 500,000 (in some embodiments, at least 600,000, 700,000, 800,000, 900,000 or 1,000,000) grams per mole and a hydrogenated poly(cyclic olefin). In some embodiments, the solventless extruding is carried out at a temperature sufficient to decrease the weight average molecular weight of the polyisobutylene resin to less than 300,000 (in some embodiments, up to 280,000, 275,000, 270,000, 260,000, 250,000, 240,000, 230,000, 220,000, 210,000, or 200,000) grams per mole such that a pressure sensitive adhesive comprising polyisobutylene having a weight average molecular weight less than 300,000 (in some embodiments, up to 280,000, 275,000, 270,000, 260,000, 250,000, 240,000, 230,000, 220,000, 210,000, or 200,000) grams per mole and a hydrogenated hydrocarbon tackifier is formed. In some embodiments, the extrusion temperature is in a range from 200° C. to 300° C., 220° C. to 280° C., or from 240° C. to 275° C.

In some embodiments of the PSA and/or the method of making the PSA according to the present disclosure, the PSA film is formed into a roll. PSAs that are at least 0.25 mm thick can be collected and stored in roll form using techniques known to one of skill in the art. Process parameters such as winding tension, diameter of the core the material is wound around, the number of liners used (single or double), and the liner material selection, specifically the liner modulus of elasticity and thickness, can be varied to improve the formation of the roll.

Optionally PSAs according to and/or useful for practicing the present disclosure and extrudable compositions disclosed herein comprises at leas one of a uv absorber (UVA), a hindered amine light stabilizer, or an antioxidant. Examples of useful UVAs include those described above in conjunction with multi-layer film substrates (example. g., those available from Ciba Specialty Chemicals Corporation under the trade designations “TINUVIN 328”, “TINUVIN 326”, “TINUVIN 783”, “TINUVIN 770”, “TINUVIN 479”, “TINUVIN 928”, and “TINUVIN 1577”). UVAs, when used, can be present in an amount from about 0.01 to 3 percent by weight based on the total weight of the pressure sensitive adhesive composition. Examples of useful antioxidants include hindered phenol-based compounds and phosphoric acid ester-based compounds and those described above in conjunction with multi-layer film substrates (e.g., those available from Ciba Specialty Chemicals Corporation under the trade designations “IRGANOX 1010”, “IRGANOX 1076”, and “IRGAFOS 126” and butylated hydroxytoluene (BHT)). Antioxidants, when used, can be present in an amount from about 0.01 to 2 percent by weight based on the total weight of the pressure sensitive adhesive composition. Examples of useful stabilizers include phenol-based stabilizers, hindered amine-based stabilizers (e.g., including those described above in conjunction with multi-layer film substrates and those available from BASF under the trade designation “CHIMASSORB” such as “CHIMASSORB 2020”), imidazole-based stabilizers, dithiocarbamate-based stabilizers, phosphorus-based stabilizers, and sulfur ester-based stabilizers. Such compounds, when used, can be present in an amount from about 0.01 to 3 percent by weight based on the total weight of the pressure sensitive adhesive composition.

### Other Optional Features

Optionally, assemblies according to the present disclosure can contain desiccant. In some embodiments, assemblies according to the present disclosure are essentially free of desiccant. “Essentially free of desiccant” means that desiccant may be present but in an amount that is insufficient to effectively dry a photovoltaic module. Assemblies that are essentially free of desiccant include those in which no desiccant is incorporated into the assembly.

In some embodiments, assemblies according to the present disclosure comprise a release liner in intimate contact with the major surface of the PSA opposite the barrier film (i.e., the fourth major surface). The release liner may be useful, for example, for protecting the PSA before bonding the assembly to a device to be encapsulated (e.g., a thin film solar device). In some embodiments, the release liner is flexible enough to allow the assembly disclosed herein to be wound into a roll. Examples of useful release liners known in the art include kraft paper coated with, for example, silicones; polypropylene film; fluoropolymer films such as those available from E.I. du Pont de Nemours and Co., Wilmington, Del., under the trade designation “TEFLON”; and polyester and other polymer films coated with, for example, silicones or fluorocarbons. In some embodiments, the release liner is a microstructured release liner such as those described in U.S. Pat. App. Pub. Nos. US2007-021235 (Sherman et al.) and US2003-129343 (Galkiewicz et al.) and PCT Int. Appl. Pub. No. WO09/058,466 (Sherman et al.). Microstructured release liners may be useful, for example, for preventing air bubbles from being trapped in the pressure sensitive adhesive layer.

Various functional layers or coatings can optionally be added to the assemblies disclosed herein to alter or improve their physical or chemical properties. Exemplary useful layers or coatings include visible and infrared light-transmissive conductive layers or electrodes (e.g., of indium tin oxide); antistatic coatings or films; flame retardants; abrasion resistant or hardcoat materials; optical coatings; anti-fogging materials; anti-reflection coatings; anti-smudging coatings; polarizing coatings; anti-fouling materials; prismatic films; additional adhesives (e.g., pressure sensitive adhesives or hot melt adhesives); primers to promote adhesion to adjacent layers; additional UV protective layers; and low adhesion backsize materials for use when the barrier assembly is to be used in adhesive roll form. These components can be incorporated, for example, into the barrier film or can be applied to the surface of the polymeric film substrate.

Other optional features that can be incorporated into the assembly disclosed herein include graphics and spacer structures. For example, the assembly disclosed herein could be treated with inks or other printed indicia such as those used to display product identification, orientation or alignment information, advertising or brand information, decoration, or other information. The inks or printed indicia can be provided using techniques known in the art (e.g., screen printing, inkjet printing, thermal transfer printing, letterpress printing, offset printing, flexographic printing, stipple printing, and laser printing). Spacer structures could be included, for example, in the adhesive, to maintain specific bond line thickness.

The present disclosure provides a method of making an assembly disclosed herein. In some embodiments, the method comprises providing the polymeric film substrate with its major surface in intimate contact with the first major surface of the barrier film; extruding the pressure sensitive adhesive using solventless extrusion; and applying the pressure sensitive adhesive (e.g., the third major surface of the pressure sensitive adhesive) to the second major surface of the barrier film. In some embodiments, the PSA is extruded between two release liners, and one of the release liners is removed before applying the PSA to the barrier film. The PSA (e.g., the third major surface of the PSA) can be applied to the second major surface of the barrier film may be carried out, for example, under vacuum and/or at room temperature.

The polymeric film substrate with its major surface in intimate contact with the first major surface of the barrier film can be made, for example, using the methods described above for making a barrier film. In some embodiments, the method of making an assembly disclosed herein comprises forming a first polymer layer on the major surface of the polymeric film substrate; forming an inorganic barrier layer on the first polymer layer; and forming a second polymer layer on the inorganic barrier layer.

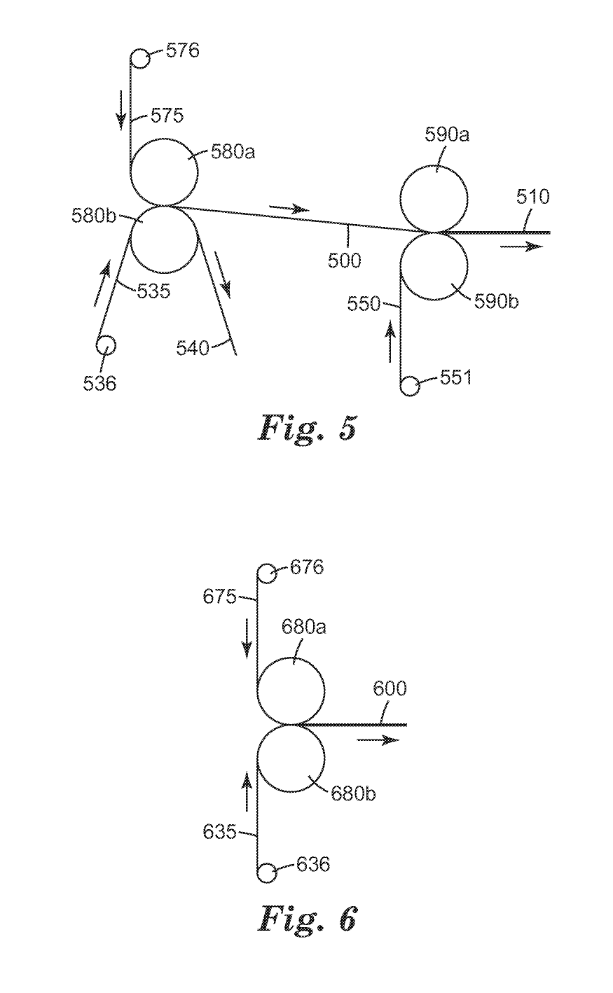

FIG. 6 is a schematic illustration of an apparatus for applying a pressure sensitive adhesive to the barrier film. Referring to FIG. 6, the polymeric film substrate and barrier film construction 675 is provided from roll 676. PSA layer 635 is provided from roll 636. In the illustrated embodiment, PSA layer 635 typically includes a release liner. The polymeric film substrate and barrier film construction 675 and the PSA layer 635 (e.g., including a release liner) are fed into a nip formed by rollers 680a and 680b to provide an assembly according to the present disclosure, as shown, for example, in any of FIGS. 1, 2, 3A, and 3B in the form of a continuous web 600. In some embodiments, the rollers may be heated. The continuous web may be formed into a roll (not shown) using techniques known in the art. Various parameters in the roll formation (e.g., winding tension, diameter of the core the material is wound around, the number of liners used (single or double), and the liner material selection, specifically the liner modulus of elasticity and thickness) may be adjusted to form a stable roll with minimal buckling as would be understood by one skilled in the art. Although FIG. 6 depicts a method of making an assembly disclosed herein in a continuous process, a batch process could also be used.

Assemblies according to the present disclosure are useful, for example, for encapsulating solar devices. In some embodiments, the assembly is disposed on, above, or around a photovoltaic cell. Accordingly, the present disclosure provides a method comprising applying an assembly disclosed herein to the front surface of a photovoltaic cell. Suitable solar cells include those that have been developed with a variety of materials each having a unique absorption spectra that converts solar energy into electricity. Each type of semiconductor material will have a characteristic band gap energy which causes it to absorb light most efficiently at certain wavelengths of light, or more precisely, to absorb electromagnetic radiation over a portion of the solar spectrum. Examples of materials used to make solar cells and their solar light absorption band-edge wavelengths include: crystalline silicon single junction (about 400 nm to about 1150 nm), amorphous silicon single junction (about 300 nm to about 720 nm), ribbon silicon (about 350 nm to about 1150 nm), CIS (Copper Indium Selenide) (about 400 nm to about 1300 nm), CIGS (Copper Indium Gallium di-Selenide) (about 350 nm to about 1100 nm), CdTe (about 400 nm to about 895 nm), GaAs multi junction (about 350 nm to about 1750 nm). The shorter wavelength left absorption band edge of these semiconductor materials is typically between 300 nm and 400 nm. One skilled in the art understands that new materials are being developed for more efficient solar cells having their own unique longer wavelength absorption band-edge and the multilayer reflective film would have a corresponding reflective band-edge. In some embodiments, the assembly disclosed herein is disposed on, above, or around a CIGS cell.

In some embodiments of assemblies and methods according to the present disclosure, the solar device (e.g., the photovoltaic cell) to which the assembly is applied comprises a flexible film substrate. Advantageously, in some of these embodiments, the assembly can be applied to the device using roll-to-roll processing. In some of these embodiments, the assembly according to the present disclosure in the form of a continuous web 600 described that includes a release liner can be fed into a nip formed by a pair of rollers after removal of the release liner. At the same time a flexible film solar device (e.g., CIGS) can be fed into the nip to provide the encapsulated device upon exiting the rollers.

Another exemplary method and apparatus for carrying out roll-to-roll processing according to the present disclosure is illustrated in FIG. 5. Referring now to FIG. 5, the polymeric film substrate and barrier film construction 575 is provided from roll 576. PSA layer 535, which in this embodiment includes a release liner 540, is provided from roll 536. The polymeric film substrate and barrier film construction 575 and the PSA layer 535 including release liner 540 are fed into a nip formed by rollers 580a and 580b. In the illustrated embodiment, after emerging from rollers 580a and 580b, release liner 540 is removed. The resulting assembly comprising the polymeric film substrate, the barrier film, and the PSA in the form of continuous web 500 is then fed, along with flexible film solar device (e.g., CIGS) 550 from roll 551, through rollers 590a and 590b to form the a continuous web comprising the top encapsulation layer and encapsulated device 510. The flexible film solar device 550 may be provided with a backsheet or other bottom encapsulation layer. Alternatively, a backsheet or other bottom encapsulation layer may be provided in a subsequent step. The PSA layer 535 may also be useful, for example, for attaching the device to the backsheet or other bottom encapsulation layer. The positions of construction 575 and flexible film 550 can be reversed if desired.

### SELECTED EMBODIMENTS OF THE DISCLOSURE

In a first embodiment, the present disclosure provides an assembly comprising:

a pressure sensitive adhesive layer at least 0.25 mm in thickness disposed on a barrier assembly, wherein the barrier assembly comprises a polymeric film substrate and a barrier film, and wherein the assembly is flexible and transmissive to visible and infrared light.

In a second embodiment, the present disclosure provides an assembly according to the first embodiment, wherein the polymeric film substrate has a major surface, the barrier film has opposing first and second major surfaces, and the pressure sensitive adhesive layer has opposing third and fourth major surfaces, wherein the first major surface of the barrier film is disposed on the major surface of the polymeric film substrate, and wherein the third major surface of the pressure sensitive adhesive is disposed on the second major surface of the barrier film.

In a third embodiment, the present disclosure provides an assembly according to the first or second embodiment, wherein the pressure sensitive adhesive comprises polyisobutylene.

In a fourth embodiment, the present disclosure provides an assembly according to the third embodiment, wherein the polyisobutylene has a weight average molecular weight of less than 300,000 grams per mole, and wherein the pressure sensitive adhesive further comprises a hydrogenated hydrocarbon tackifier.

In a fifth embodiment, the present disclosure provides an assembly according to any preceding embodiment, wherein the pressure sensitive adhesive has a glass transition temperature of up to 0° C.

In a sixth embodiment, the present disclosure provides an assembly according to any preceding embodiment, wherein the pressure sensitive adhesive is free of added solvent.

In a seventh embodiment, the present disclosure provides an assembly according to any preceding embodiment, wherein the pressure sensitive adhesive further comprises at least one of a ultraviolet absorber, a hindered amine light stabilizer, or an antioxidant.

In an eighth embodiment, the present disclosure provides an assembly according to any preceding embodiment, wherein the polymeric film substrate comprises a fluoropolymer.

In a ninth embodiment, the present disclosure provides an assembly according to the eighth embodiment, wherein the fluoropolymer comprises at least one of an ethylene tetrafluoro-ethylene copolymer, a tetrafluoroethylene-hexafluoropropylene copolymer, a tetrafluoroethylene-hexafluoropropylene-vinylidene fluoride copolymer, polyvinylidene fluoride, or a blend of polyvinylidene fluoride and polymethyl methacrylate.

In a tenth embodiment, the present disclosure provides an assembly according to any preceding embodiment, wherein the polymeric film substrate is a multi-layer optical film.

In an eleventh embodiment, the present disclosure provides an assembly according to the tenth embodiment, wherein the polymeric film substrate comprises an ultraviolet-reflective multilayer optical film having first and second major surfaces and comprising an ultraviolet-reflective optical layer stack, where the ultraviolet-reflective optical layer stack comprises first optical layers and second optical layers, wherein at least a portion of the first optical layers and at least a portion of the second optical layers are in intimate contact and have different refractive indexes, and wherein the multilayer optical film further comprises a ultraviolet absorber in at least one of the first optical layer, the second optical layer, or a third layer disposed on at least one of the first or second major surfaces.

In a twelfth embodiment, the present disclosure provides an assembly according to the eleventh embodiment, wherein the multilayer optical film reflects at least 50 percent of incident ultraviolet light over at least a 30 nanometer range in a wavelength range from at least 300 to 400 nanometers.

In a thirteenth embodiment, the present disclosure provides an assembly according to any preceding embodiment, wherein the barrier film comprises at least first and second polymer layers separated by an inorganic barrier layer.

In a fourteenth embodiment, the present disclosure provides an assembly according to any preceding embodiment, wherein the barrier film has at least one of an oxygen transmission rate less than 0.005 cc/m²/day at 23° C. and 90% relative humidity or a water vapor transmission rate less than 0.05 cc/m²/day at 50° C. and 100% relative humidity.

In a fifteenth embodiment, the present disclosure provides an assembly according to any preceding embodiment, further comprising a release liner in intimate contact with the fourth major surface of the pressure sensitive adhesive.

In a sixteenth embodiment, the present disclosure provides an assembly according to any preceding embodiment, wherein the assembly is in the form of a roll.

In a seventeenth embodiment, the present disclosure provides an assembly according to any one of the first to fourteenth embodiments, wherein the assembly is disposed on, above, or around a photovoltaic cell.

In an eighteenth embodiment, the present disclosure provides an assembly according to the seventeenth embodiment, wherein the photovoltaic cell is a CIGS cell.

In a nineteenth embodiment, the present disclosure provides a method of making the assembly according to any one of the first to sixteenth embodiments, the method comprising:

providing the barrier assembly comprising the polymeric film substrate and the barrier film;

extruding the pressure sensitive adhesive using solventless extrusion; and

applying the pressure sensitive adhesive to the barrier assembly.

In a twentieth embodiment, the present disclosure provides a method according to the nineteenth embodiment, wherein the pressure sensitive adhesive is extruded between two release liners, and wherein one of the release liners is removed before applying the pressure sensitive adhesive to the barrier film.

In a twenty-first embodiment, the present disclosure provides a method according to the nineteenth or twentieth embodiment, wherein the assembly is formed into a roll.

In a twenty-second embodiment, the present disclosure provides a method according to any one of the nineteenth to twenty-first embodiments, further comprising:

forming a first polymer layer on the major surface of the polymeric film substrate;

forming an inorganic barrier layer on the first polymer layer; and

forming a second polymer layer on the inorganic barrier layer.

In a twenty-third embodiment, the present disclosure provides a method of making a photovoltaic module, the method comprising:

applying the assembly according to any one of the first to fourteenth embodiments to the front surface of a photovoltaic cell.

In a twenty-fourth embodiment, the present disclosure provides a method according to the twenty-third embodiment, wherein the photovoltaic cell comprises a flexible film substrate.

In a twenty-fifth embodiment, the present disclosure provides a method according to the twenty-third or twenty-fourth embodiment, wherein the assembly is not heated after applying the assembly to the front surface of the photovoltaic cell.

In a twenty-sixth embodiment, the present disclosure provides a pressure sensitive adhesive comprising:

a polyisobutylene having a weight average molecular weight less than 300,000 grams per mole; and

a hydrogenated hydrocarbon tackifier,

wherein the pressure sensitive adhesive is in the form of a film at least 0.25 mm thick.

In a twenty-seventh embodiment, the present disclosure provides a pressure sensitive adhesive according to the twenty-sixth embodiment, wherein the pressure sensitive adhesive film has a glass transition temperature of up to 0° C.

In a twenty-eighth embodiment, the present disclosure provides a pressure sensitive adhesive according to the twenty-sixth or twenty-seventh embodiment, further comprising at least one of an ultraviolet absorber, a hindered amine light stabilizer, or an antioxidant.

In a twenty-ninth embodiment, the present disclosure provides a pressure sensitive adhesive according to any one of the twenty-sixth to twenty-eighth embodiments, wherein the hydrogenated hydrocarbon tackifier is present in an amount of less than 20 percent by weight, based on the total weight of the pressure sensitive adhesive.

In a thirtieth embodiment, the present disclosure provides a method of making a pressure sensitive adhesive, the method comprising:

extruding by solventless extrusion an extrudable composition comprising a polyisobutylene having a weight average molecular weight of at least 500,000 grams per mole and a hydrogenated hydrocarbon tackifier, wherein the extruding is carried out at a temperature sufficient to decrease the weight average molecular weight of the polyisobutylene resin to less than 300,000 grams per mole such that a pressure sensitive adhesive comprising a hydrogenated hydrocarbon tackifier and polyisobutylene resin having a weight average molecular weight less than 300,000 grams per mole is formed.

In a thirty-first embodiment, the present disclosure provides a method according to the thirtieth embodiment, wherein the pressure sensitive adhesive has a glass transition temperature of up to 0° C.

In a thirty-second embodiment, the present disclosure provides a method according to the thirtieth or thirty-first embodiment, wherein the extrudable composition further comprises at least one of an ultraviolet absorber, a hindered amine light stabilizer, or an antioxidant.

In a thirty-third embodiment, the present disclosure provides a method according to the any one of the thirtieth to thirty-second embodiments, wherein the hydrogenated hydrocarbon tackifier is present in an amount of less than 20 percent by weight, based on the total weight of the pressure sensitive adhesive.

In a thirty-fourth embodiment, the present disclosure provides a method according to the any one of the thirtieth to thirty-third embodiments, wherein extrudable composition is extruded between two release liners.

In a thirty-fifth embodiment, the present disclosure provides a method according to the any one of the thirtieth to thirty-fourth embodiments, wherein the extrudable composition is extruded under vacuum.

In a thirty-sixth embodiment, the present disclosure provides a method according to the any one of the thirtieth to thirty-fifth embodiments, wherein the extrudable composition is free of added solvent.

In order that this disclosure can be more fully understood, the following examples are set forth. It should be understood that these examples are for illustrative purposes only, and are not to be construed as limiting this disclosure in any manner.

### EXAMPLES

### Front Side Barrier Film

An ethylene-tetrafluoroethylene (ETFE) support film was treated with a nitrogen plasma and then covered respectively with barrier layers of acrylate, silicon aluminum oxide (SiAlOx), silicon-sub-oxide (SiOx), and a second acrylate. Examples of barrier assemblies were made on a vacuum coater similar to the coater described in U.S. Pat. Nos. 5,440,446 (Shaw et al.) and 7,018,713 (Padiyath, et al.). The individual layers were formed as follows:

A 300 meter long roll of 0.127 mm thick×305 mm wide surface treated (C-treated) ETFE film (commercially available under the trade name “Norton ETFE” from St. Gobain Performance Plastics, Wayne, N.J.) was loaded into a roll-to-roll vacuum processing chamber with the C-treated side facing “up” and the non-C-treated side in contact with the coating drum. The chamber was pumped down to a pressure of 2×10⁻⁵ Ton (2.7×10⁻³ Pa). The web speed was maintained at 1.5 meters/min while maintaining the backside of the film in contact with a coating drum chilled to −10° C. With the backside of the ETFE film in contact with the drum, the front side film surface was treated with a nitrogen plasma formed by flowing 100 standard cubic centimeters per minute (sccm) of nitrogen over a magnetically enhanced cathode in the presence of 0.1 kW of power (obtained from ENI Products, Rochester, N.Y., under the trade designation “ENI DCG-100”). Immediately after the nitrogen plasma treatment, the film was coated with tricyclodecane dimethanol di-acrylate (commercially available under the trade name SR-833S from Sartomer Company, Inc. Exton, Pa.). The di-acrylate was degassed to a pressure of 20 mTorr (2.7 Pa) prior to coating, and pumped at a flow rate of 0.35 mL/min through an ultrasonic atomizer (Sono-Tek Corporation) operated at a frequency of 60 kHz into a heated vaporization chamber maintained at 260° C. The resulting monomer vapor stream condensed onto the film surface and was polymerized after electron beam exposure using a multi-filament electron gun operated at 9.0 kV and 3.1 mA to form a 780 nm acrylate layer.

Immediately after the acrylate deposition and with the film still in contact with the drum, a SiAlOx layer was sputter-deposited atop a 60 meter length of the plasma treated and acrylate-coated ETFE film surface. Two alternating current (AC) power supplies (obtained from Advanced Energy, Fort Collins, Colo., under the trade designation “PE-II”) were used to control two pairs of cathodes, with each cathode housing two targets. Each cathode pair contained two 90% Si/10% Al targets (targets commercially available from Academy Precision Materials, Albuquerque, N. Mex. 87109). During sputter deposition, the voltage signal from each power supply was used as an input for a proportional-integral-differential control loop to maintain a proscribed oxygen flow to each cathode pair. The AC power supplies sputtered the 90% Si/10% Al targets using 3800 watts of power each, and a total gas mixture containing 600 sccm argon and 37 sccm oxygen at a sputter pressure of 2.45 millitorr (0.33 Pa). This provided a 40 nm thick SiAlOx layer deposited atop the acrylate coating.

Immediately after the SiAlOx deposition and with the film still in contact with the drum, a sub-oxide of silicon (SiOx, where x<2) tie-layer was sputter deposited atop the same 60 meter length of the SiAlOx and acrylate coated ETFE film surface using a 99.999% Si target (commercially available from Academy Precision Materials, Albuquerque, N. Mex. 87109). The SiOx was sputtered using 1000 watts of pulsed-DC power (obtained from Advanced Energy) at a frequency of 90 kHz, a reverse time of 4.4 microseconds, and a reverse voltage set to 10% of the DC voltage using a gas mixture containing 10 sccm of oxygen at a sputter pressure of 2 millitorr (0.27 Pa) to provide a SiOx layer 5 nm thick atop SiAlOx layer.

Immediately after the SiOx layer deposition and with the film still in contact with the drum, a second acrylate was coated and cross linked on the same 60 meter web length using the same conditions as for the first acrylate layer but with the following exceptions: electron beam cross linking was carried out using a multi-filament cure gun operated at 9 kV and 0.41 mA. This provided a 780 nm acrylate layer.

The resulting stack exhibited an average spectral transmission Tvis=91.2% (determined by averaging the percent transmission T between 400 nm and 1400 nm) measured at a 0° angle of incidence. A water vapor transmission rate was measured in accordance with ASTM F-1249 at 50° C. and 100% RH using a WVTR tester obtained from MOCON, Inc., Minneapolis, Minn., under the trade designation “MOCON PERMATRAN-W” Model 700. The result was 0.009 g/m2/day.

ETFE Film without Barrier Coating

A sample of surface treated (C-treated) ethylene tetrafluoroethylene (ETFE) support film (commercially available under the trade name “NORTON ETFE” from St. Gobain Performance Plastics, Wayne, N.J.) exhibited an average spectral transmission Tvis=91.2% (determined by averaging the percent transmission T between 400 nm and 1400 nm) measured at a 0° angle of incidence. A water vapor transmission rate was measured in accordance with ASTM F-1249 at 50° C. and 100% RH using a WVTR tester obtained from MOCON, Inc. under the trade designation “MOCON PERMATRAN-W” Model 700. The result was 6.6 g/m2/day.

### Pressure Sensitive Adhesive

Pressure sensitive adhesive encapsulant was prepared by cutting a polyisobutene sheet (commercially available under the trade designation “OPPANOL B100” from BASF Corporation, Florham Park, N.J.) into 2″×1.5″×12″ strips. These strips were fed into a 2 inch diameter single screw extruder (commercially available from Bonnot Co., Green, Ohio) with a packing roll to help pull the material into the screw. The B100 was extruded with the extruder operating at 500° F. (260° C.), into the second barrel section of a 10 section 40 mm ZE twin screw extruder (TSE) (commercially available from Berstorff, Florence, Ky.). The TSE had mixing sections in barrel sections 3, 5, and 7. Tackifier (obtained under the trade designation “ALCON P100” from Arakawa Chemical USA, Inc. Chicago, Ill.) and antioxidant, UV absorber, and hindered amine light stabilizer obtained under the trade designations “IRGANOX 1010”, “TINUVIN 328”, and “CHIMASSORB 2020”, respectively, from BASF Corporation Florham Park, N.J.) were added to section 4 of the TSE in the weight ratio of 85/15/1/0.5/0.5 “OPPANOL B100”/“ALCON P100”/“IRGANOX 1010”/“TINUVIN 328”/“CHIMASSORB 2020”. A vacuum level of 29.14 inches of mercury (9.9×10⁴ Pa) was pulled at a vent dome on section 8 of the TSE. The first section of the TSE was at room temperature. The following sections 2 and 3 operated at 280° C., and the remainder of the TSE operated at 220° C. TSE screw speed was 150 rpm resulting in an exiting melt temperature of 290° C. This extrudate was pumped via a 10.3 cc gear pump (commercially available from Normag, now a part of Dynisco, Franklin, Mass.) through a 40 micron candle filter and into a 14-inch (36 cm) coat-hanger manifold die. The resulting film was then quenched via a two roll nip running at a speed of 2 ft/min. The first roll was covered by paper liner 14 inches (36 cm) wide. The second roll of the two roll nip was placed directly above the first and was covered by polyester liner 14 inches (36 cm) wide. The samples were cut into 5 foot (1.5 meter) long sections. The pressure sensitive adhesive (PSA) was measured to be 0.46 mm thick.

For a replicate of this run, the molecular weight of the pressure sensitive adhesive was determined by comparison to linear polystyrene polymer standards using gel permeation chromatography (GPC). The GPC measurements were carried out on a Waters Alliance 2695 system (obtained from Waters Corporation, Milford, Mass.) using 30 centimeter (cm) columns (obtained from Jordi Labs, Bellingham, Mass., under the trade designation “JORDI FLP”). A refractive index detector from Shimadzu Scientific Inc. (model RID-10A) was used at 35° C. A 25-milligram (mg) sample of the PSA was diluted with 10 milliliters (mL) of tetrahydrofuran and filtered through a 0.25 micrometer syringe filter. A sample volume of 100 microliters was injected onto the column, and the column temperature was 35° C. A flow rate of 1 mL/minute was used, and the mobile phase was tetrahydrofuran. Molecular weight calibration was performed using narrow dispersity polystyrene standards with peak average molecular weights ranging from 7.5×10⁶ grams per mole to 580 grams per mole. Calibration and molecular weight distribution calculations were performed using CIRRUS GPC software from Polymer Laboratories, Shropshire, UK. The weight average molecular weight of the polyisobutylene was determined to be 1.98×10⁵, and the number average molecular weight was determined to be 9.21×10⁴, with a polydispersity of 2.15. Using the same method, the weight average molecular weight of starting polyisobutylene (“OPPANOL B100”) was determined to be 1.43×10⁶, and the number average molecular weight was determined to be 2.51×10⁵, with a polydispersity of 5.69.

### Comparative Example 1A

### Humidity Indicator Sensor with ETFE Film and Thermally Cured Encapsulant A 152 mm×152 mm laminate comprising the following layers was stacked in the following order:

(Layer 1) A 152 mm×152 mm solar backsheet film (commercially available under the trade designation “TAPE” from Madico Woburn, Mass.) was orientated with the 100 micron ethylene vinylacetate (EVA) layer facing up.

(Layer 2) A 152 mm×152 mm encapsulant sheet 0.66 mm thick (commercially available under the trade designation “HELIOBOND PVA 100” from Adco Product, Inc. Michigan Center, Mich.) was placed directly on top of Layer 1.

(Layer 3) A 114 mm×114 mm humidity indicator card (obtained from Sud-Chemie Performance Packaging Colton, Calif., under the trade designation “HUMITECTOR Maximum Humidity Indicator P/N MXC-56789”) was placed in the center directly on top of Layer 2.

(Layer 4) Another 152 mm×152 mm encapsulant sheet 0.66 mm thick (commercially available under the trade designation “HELIOBOND PVA 100” from Adco Product, Inc. Michigan Center, Mich.) was placed directly on top of Layer 3.

(Layer 5) A 152 mm×152 mm sample of surface treated (C-treated) ethylene tetrafluoroethylene (ETFE) support film (commercially available from St. Gobain Performance Plastics Wayne, N.J.) with the C-treated side orientated toward Layer 4 was placed directly on top of Layer 4. These layers were then placed into a Spire 350 Vacuum Laminator (commercially available from Spire Corporation Bedford, Mass.). The laminate was then cured for 12 minutes at 150° C. under 1 atm (1×10⁵ Pa) of pressure. The resulting laminate was than placed in an environmental chamber at 85° C. and 85% relative humidity (RH) for a period of 168 hours. Upon 168 hours of 85° C. and 85% RH exposure the humidity indicator card was visually examined and the 80% indicator had dissolved crystals. This indicates that the humidity indicator sensor was exposed to at least 80% RH for 24 hours. The data is reported in Table 1 (CE1A).

### Comparative Example 1B

### No Humidity Indicator Sample for Peel Test

A 178 mm wide×178 mm long laminate (having a 25-mm unbonded end for clamping in the grips of the test machine) for T-Peel testing was made comprising the following layers that were stacked in the following order:

(Layer 1) A 178 mm×178 mm solar backsheet film (commercially available under the trade designation “TAPE” from Madico Woburn, Mass.) was orientated with the 100 micron ethylene vinylacetate (EVA) layer facing up.

(Layer 2) A 178 mm wide×152 mm long EVA film (commercially available under the trade designation “HELIOBOND PVA 100” from Adco Product, Inc. Michigan Center, Mich.) was placed on top of Layer 1 leaving a 25-mm tab are exposed.

(Layer 3) A 178 mm×178 mm sample of surface treated (C-treated) ethylene tetrafluoroethylene (ETFE) support film (commercially available from St. Gobain Performance Plastics Wayne, N.J.) with the C-treated side orientated toward Layer 2 was placed such that is directly aligned on top of Layer 1 and completely covering Layer 2. These layers were then placed into a Spire 350 Vacuum Laminator (commercially available from Spire Corporation Bedford, Mass.). The laminate was then cured for 12 minutes at 150° C. and 1 atm (1×10⁵ Pa) of pressure. The resulting laminate was than cut into 25 mm wide×152 mm long strips such that one end contains the 25-mm unbonded films that are to be placed in the clamping grips of the test machine. The two unbonded ends of film were placed in a tension testing machine according to ASTM D1876-08 “Standard Test Method for Peel Resistance of Adhesives (T-Peel Test). A grip distance of 12.7 mm was used. T-Peel testing was than completed according to ASTM D1876-08. An initial T-Peel average value of 46.1 N/cm was measured and is reported in Table 1 (CE1B). The remaining 25-mm strips were placed in an environmental chamber at 85° C. and 85% relative humidity (RH) for a period of 212 hours. Upon 212 hours of 85° C. and 85% RH exposure, T-Peel testing was than completed according to ASTM D1876-08 again using a grip distance of 12.7 mm. A T-Peel average of 5.6 N/cm was measured and is reported in Table 1 (CE1B).

### Comparative Example 2A

### Humidity Indicator Sensor with Front Side Barrier Film and Thermally Cured Encapsulant

A 152 mm×152 mm laminate was prepared as in Comparative Example 1A except that a different Layer 5 was used.

(Layer 5) A 152 mm×152 mm sample of barrier film as described above under “Front Side Barrier Film” with the barrier coating orientated toward Layer 4 was placed directly on top of Layer 4. These layers were then placed into a Spire 350 Vacuum Laminator (commercially available from Spire Corporation Bedford, Mass.). The laminate was then cured for 12 minutes at 150° C. under 1 atm (1×10⁵ Pa) of pressure. The resulting laminate was than placed in an environmental chamber at 85° C. and 85% RH for a period of 500 hours. Upon 500 hours of 85° C. and 85% RH exposure the humidity indicator card obtained from Sud-Chemie Performance Packaging Colton, Calif., under the trade designation “HUMITECTOR Maximum Humidity Indicator P/N MXC-56789” was visually examined and the 50% indicator had dissolved crystals. This indicates that the humidity indicator sensor was exposed to at least 50% RH for 24 hours. The data is reported in Table 1 (CE2A).

### Comparative Example 2B

### No Humidity Indicator Sample for Peel Test

A 178 mm wide×178 mm long laminate (having a 25-mm unbonded end for clamping in the grips of the test machine) for T-Peel testing was made comprising the following layers that were stacked in the following order:

(Layer 1) A 178 mm×178 mm solar backsheet film (commercially available under the trade designation “TAPE” from Madico Woburn, Mass.) was orientated with the 100 micron ethylene vinylacetate (EVA) layer facing up.

(Layer 2) A 178 mm wide×152 mm long EVA film (commercially available under the trade designation “HELIOBOND PVA 100” from Adco Product, Inc. Michigan Center, Mich.) was placed on top of Layer 1 leaving a 25-mm tab are exposed.

(Layer 3) A 178 mm×178 mm sample of barrier film as described above under “Front Side Barrier Film” with the barrier coating orientated toward Layer 2 was placed such that is directly aligned on top of Layer 1 and completely covering Layer 2. These layers were then placed into a Spire 350 Vacuum Laminator (commercially available from Spire Corporation Bedford, Mass.). The laminate was then cured for 12 minutes at 150° C. and 1 atm of pressure. The resulting laminate was than cut into 25 mm wide×152 mm long strips such that one end contains the 25 mm unbonded films that are to be placed in the clamping grips of the test machine. The two unbonded ends of film were placed in a tension testing machine according to ASTM D1876-08 “Standard Test Method for Peel Resistance of Adhesives (T-Peel Test)” using a grip distance of 12.7 mm. T-Peel testing was than completed according to ASTM D1876-08. An initial T-Peel average value of 5.6 N/cm was measured and is reported in Table 1 (CE2B). The remaining 25-mm strips were placed in an environmental chamber at 85° C. and 85% relative humidity (RH) for a period of 212 hours. Upon 212 hours of 85° C. and 85% RH exposure, T-Peel testing was than completed according to ASTM D1876-08, again using a grip distance of 12.7 mm. An average T-Peel of 0.1 N/cm was measured and is reported in Table 1 (CE2B).

### Comparative Example 3A

### Humidity Indicator Sensor with ETFE Film and PSA Encapsulant

A 152 mm×152 mm laminate comprising the following layers was assembled at room temperature ambient conditions using hand pressure and a felt squeegee via the following procedure:

(Layer 1) A 152 mm×152 mm solar backsheet film (commercially available under the trade designation “TAPE” from Madico Woburn, Mass.) was orientated with the 100 micron ethylene vinylacetate (EVA) layer facing up.

(Step 2) A 152 mm×152 mm sample of PSA as described above under “Pressure Sensitive Adhesive” was laminated at room temperature ambient conditions to the top of Layer 1 by first removing the paper release liner and using hand pressure and a felt squeegee against the remaining polyester release liner and adhesive. This procedure is meant to simulate a roll to roll type of process and best efforts to eliminate air entrapment between the backsheet and the PSA.

(Step 3) A 152 mm×152 mm sample of PSA as described above under “Pressure Sensitive Adhesive” was laminated at room temperature ambient conditions to the surface treated (C-treated) ethylene tetrafluoroethylene (ETFE) support film (commercially available from St. Gobain Performance Plastics Wayne, N.J.) by removing the paper release liner and using hand pressure and a felt squeegee against the remaining polyester release liner and adhesive. This procedure is meant to simulate a roll to roll type of process and best efforts to eliminate air entrapment between the ETFE and the PSA.

(Step 4) The polyester release liner was removed from PSA and backsheet identified in step 2. A 114 mm×114 mm humidity indicator card (obtained from Sud-Chemie Performance Packaging Colton, Calif., under the trade designation “HUMITECTOR Maximum Humidity Indicator P/N MXC-56789”) was placed in the center directly on top of PSA.

(Step 5) The polyester release liner was removed from PSA and ETFE identified in Step 3. Hand pressure and a felt squeegee were used to laminate the PSA and ETFE to the humidity indicator and PSA surface from step 4. This procedure is meant to simulate a roll to roll type of process and best efforts to eliminate air entrapment between layers. The resulting laminate was than placed in an environmental chamber at 85° C. and 85% RH for a period of 168 hours. Upon 168 hours of 85° C. and 85% RH exposure the humidity indicator card was visually examined and the 80% indicator had dissolved crystals. This indicates that the humidity indicator sensor was exposed to at least 80% RH for 24 hours. The data is reported in Table 1 (CE3A).

### Comparative Example 3B

### No Humidity Indicator Sample for Peel Test

A 178 mm wide×178 mm long laminate (having a 1″ unbonded end for clamping in the grips of the test machine) for T-Peel testing was made comprising the following layers that were stacked in the following order:

(Layer 1) A 178 mm×178 mm solar backsheet film (commercially available under the trade designation “TAPE” from Madico Woburn, Mass.) was orientated with the 100 micron ethylene vinylacetate (EVA) layer facing up.

(Layer 2) A 178 mm wide×152 mm long sample of PSA as described above under “Pressure Sensitive Adhesive” was laminated at room temperature ambient conditions to the top of Layer 1 by first removing the paper release liner and using hand pressure and a felt squeegee against the remaining polyester release liner and adhesive. This procedure is meant to simulate a roll to roll type of process and best efforts to eliminate air entrapment between the backsheet and the PSA.

(Layer 3) The polyester release liner was removed from PSA and backsheet identified in step 2. A 178 mm×178 mm sample of surface treated (C-treated) ethylene tetrafluoroethylene (ETFE) support film (commercially available from St. Gobain Performance Plastics Wayne, N.J.) with the C-treated side orientated toward Layer 2 was placed such that it is directly aligned on top of Layer 1 and completely covering Layer 2. Hand pressure and a felt squeegee were used to laminate the PSA and ETFE to Layer 2. This procedure is meant to simulate a roll to roll type of process and best efforts to eliminate air entrapment between layers. The resulting laminate was than cut into 25 mm wide×152 mm long strips such that one end contains the 25 mm unbonded films that are to be placed in the clamping grips of the test machine. The two unbonded ends of film were placed in a tension testing machine according to ASTM D1876-08 “Standard Test Method for Peel Resistance of Adhesives” (T-Peel Test) using a grip distance of 12.7 mm. T-Peel testing was than completed according to ASTM D1876-08. An initial average T-Peel value of 13.1 N/cm was measured and is reported in Table 1 (CE3B). The remaining 25 mm strips were placed in an environmental chamber at 85° C. and 85% relative humidity (RH) for a period of 212 hours. Upon 212 hours of 85° C. and 85% RH exposure, T-Peel testing was than completed according to ASTM D1876-08 again using a grip distance of 12.7 mm. An average T-Peel of 12.3 N/cm was measured and is reported in Table 1 (CE3B).

### Example 1A

### Humidity Indicator Sensor with Front Side Ultra Barrier Film and PSA Encapsulant

A 152 mm×152 mm laminate comprising the following layers was assembled at room temperature ambient conditions using hand pressure and a felt squeegee via the following procedure:

(Layer 1) A 152 mm×152 mm solar backsheet film (commercially available under the trade designation “TAPE” from Madico Woburn, Mass.) was orientated with the 100 micron ethylene vinylacetate (EVA) layer facing up.

(Step 2) A 152 mm×152 mm sample of PSA as described above under “Pressure Sensitive Adhesive” was laminated at room temperature ambient conditions to the top of Layer 1 by first removing the paper release liner and using hand pressure and a felt squeegee against the remaining polyester release liner and adhesive. This procedure is meant to simulate a roll to roll type of process and best efforts to eliminate air entrapment between the backsheet and the PSA.

(Step 3) A 152 mm×152 mm sample of PSA as described above under “Pressure Sensitive Adhesive” was laminated at room temperature ambient conditions to the barrier surface of the “Front Side Barrier Film” described above by removing the paper release liner and using hand pressure and a felt squeegee against the remaining polyester release liner and adhesive. This procedure is meant to simulate a roll to roll type of process and best efforts to eliminate air entrapment between the barrier surface and the PSA.

(Step 4) The polyester release liner was removed from PSA and backsheet identified in Step 2. A 114 mm×114 mm humidity indicator card (obtained from Sud-Chemie Performance Packaging Colton, Calif., under the trade designation “HUMITECTOR Maximum Humidity Indicator P/N MXC-56789”) was placed in the center directly on top of PSA.

(Step 5) The polyester release liner was removed from PSA and “Front Side Barrier Film” identified in Step 3. Hand pressure and a felt squeegee were used to laminate the PSA and front side barrier film to the humidity indicator and PSA surface from step 4. This procedure is meant to simulate a roll to roll type of process and best efforts to eliminate air entrapment between layers. The resulting laminate was than placed in an environmental chamber at 85° C. and 85% RH for a period of 500 hours. Upon 500 hours of 85° C. and 85% RH exposure the Humitector™ Maximum Humidity Indicator was visually examined and the 50% indicator had dissolved crystals. This indicates that the humidity indicator sensor was exposed to at least 50% RH for 24 hours. The data is summarized in Table 1.

### Example 1B

### No Humidity Indicator Sample for Peel Test

A 178 mm wide×178 mm long laminate (having a 25-mm unbonded end for clamping in the grips of the test machine) for T-Peel testing was made comprising the following layers that were stacked in the following order:

(Layer 1) A 178 mm×178 mm solar backsheet film (commercially available under the trade designation “TAPE” from Madico Woburn, Mass.) was orientated with the 100 micron ethylene vinylacetate (EVA) layer facing up.

(Layer 2) A 178 mm wide×152 mm long sample of PSA as described above under “Hot Melt Pressure Sensitive Adhesive” was laminated at room temperature ambient conditions to the top of Layer 1 by first removing the paper release liner and using hand pressure and a felt squeegee against the remaining polyester release liner and adhesive. This procedure is meant to simulate a roll to roll type of process and best efforts to eliminate air entrapment between the backsheet and the PSA.

(Layer 3) The polyester release liner was removed from PSA and backsheet identified in step 2. A 178 mm×178 mm sample of “Front Side Barrier Film” with the barrier surface facing the PSA was placed such that it is directly aligned on top of Layer 1 and completely covering Layer 2. Hand pressure and a felt squeegee were used to laminate the PSA and “Front Side Barrier Film” to Layer 2. This procedure is meant to simulate a roll to roll type of process and best efforts to eliminate air entrapment between layers. The resulting laminate was than cut into 25 mm wide×152 mm long strips such that one end contains the 25 mm unbonded films that are to be placed in the clamping grips of the test machine. The two unbonded ends of film were placed in a tension testing machine according to ASTM D1876-08 “Standard Test Method for Peel Resistance of Adhesives (T-Peel Test) using a grip distance of 12.7 mm. T-Peel testing was than completed according to ASTM D1876-08. An initial average T-Peel value of 15.4 N/cm was measured and is reported in Table 1 (EX1B). The remaining 25-mm strips were placed in an environmental chamber at 85° C. and 85% relative humidity (RH) for a period of 212 hours. Upon 212 hours of 85° C. and 85% RH exposure, T-Peel testing was than completed according to ASTM D1876-08 again using a grip distance of 12.7 mm. An average T-Peel of 13.0 N/cm was measured and is reported in Table 1 (EX1B).

TABLE 1

| | Humidity | Humidity | Initial | T-peel | |
|---|---|---|---|---|---|
| | Indicator % | Indicator % | T-peel | N/cm (lbf/in) | |
| | (168 hrs) | (500 hrs) | N/cm (lbf/in) | (212 hrs) | |
| CE1A and | 80 | NA | 46.1 N/cm | 5.6 | (3.2) |
| CE1B | | | (26.3) | | |
| CE2A and | 50 | 50 | 5.6 (3.2) | 0.1 | (0.03) |
| CE2B | | | | | |
| CE3A and | 80 | NA | 13.1 (7.5) | 12.3 | (7.0) |
| CE3B | | | | | |
| EX1A and | 50 | 50 | 15.4 (8.8) | 13.0 | (7.4) |
| EX1B | | | | | |

NA = not applicable

### Prophetic Example

Instead of the ETFE film described above, a UV reflective multilayer optical film can be used as the substrate. Nitrogen plasma surface treatment can be used as described above. The adhesion and barrier properties described above for EX1A and EX1B would be expected to be similar when the UV reflective multilayer optical film is used. A multilayer optical film can be made with first optical layers of polyethylene terephthalate (PET) (obtained from Eastman Chemical, Kingsport, Tenn., under the trade designation “EASTAPAK 7452”) and second optical layers of a copolymer of 75 weight percent methyl methacrylate and 25 weight percent ethyl acrylate (coPMMA) (obtained from Ineos Acrylics, Inc., Memphis, Tenn., under the trade designation “PERSPEX CP63”). The PET and coPMMA can be coextruded through a multilayer polymer melt manifold to form a stack of 224 optical layers. The layer thickness profile (layer thickness values) of this UV reflector can be adjusted to be approximately a linear profile with the first (thinnest) optical layers adjusted to have about a ¼ wave optical thickness (index times physical thickness) for 300 nm light and progressing to the thickest layers which can be adjusted to be about ¼ wave thick optical thickness for 400 nm light. Layer thickness profiles of such films can be adjusted to provide for improved spectral characteristics using the axial rod apparatus disclosed in U.S. Pat. No. 6,783,349 (Neavin et al.), the disclosure of which is incorporated herein by reference, combined with layer profile information obtainable with atomic force microscopic techniques. 20 wt % of UV absorber masterbatch (e.g., “Sukano TA07-07 MB”) can be extrusion compounded into both the first optical layers (PET) and second optical layers (coPMMA).

In addition to these optical layers, non-optical protective skin layers of PET1 (260 micrometers thickness each) can be coextruded on either side of the optical stack. 20 wt % of UV absorber masterbatch (e.g., “Sukano TA07-07 MB”) can be compounded into these PET protective skin layers. This multilayer coextruded melt stream can be cast onto a chilled roll at 5.4 meters per minute creating a multilayer cast web approximately 500 micrometers (20 mils) thick. The multilayer cast web can then be preheated for about 10 seconds at 95° C. and biaxially oriented at a draw ratios of 3.5×3.7. The oriented multilayer film can be further heated at 225° C. for 10 seconds to increase crystallinity of the PET layers.

All patents and publications referred to herein are hereby incorporated by reference in their entirety. Various modifications and alterations of this disclosure may be made by those skilled in the art without departing from the scope and spirit of this disclosure, and it should be understood that this disclosure is not to be unduly limited to the illustrative embodiments set forth herein.

1. An assembly comprising:
a pressure sensitive adhesive layer at least 0.25 mm in thickness disposed on a barrier assembly, wherein the barrier assembly comprises a polymeric film substrate and a barrier film, and wherein the assembly is flexible and transmissive to visible and infrared light.

2. An assembly according to claim 1, wherein the polymeric film substrate has a major surface, the barrier film has opposing first and second major surfaces, and the pressure sensitive adhesive layer has opposing third and fourth major surfaces, wherein the first major surface of the barrier film is disposed on the major surface of the polymeric film substrate, and wherein the third major surface of the pressure sensitive adhesive is disposed on the second major surface of the barrier film.

3. The assembly according to claim 1, wherein the pressure sensitive adhesive comprises polyisobutylene.

4. The assembly according to claim 1, wherein the pressure sensitive adhesive is free of added solvent.

5. The assembly according to claim 1, wherein the pressure sensitive adhesive further comprises at least one of a ultraviolet absorber, a hindered amine light stabilizer, or an antioxidant.

6. The assembly according to claim 1, wherein the polymeric film substrate comprises a fluoropolymer.

7. The assembly according to claim 1, wherein the polymeric film substrate is a multi-layer optical film.

8. The assembly according to claim 7, wherein the polymeric film substrate comprises an ultraviolet-reflective multilayer optical film having first and second major surfaces and comprising an ultraviolet-reflective optical layer stack, where the ultraviolet-reflective optical layer stack comprises first optical layers and second optical layers, wherein at least a portion of the first optical layers and at least a portion of the second optical layers are in intimate contact and have different refractive indexes, and wherein the multilayer optical film further comprises a ultraviolet absorber in at least one of the first optical layer, the second optical layer, or a third layer disposed on at least one of the first or second major surfaces.

9. The assembly according to claim 1, wherein the barrier film comprises at least first and second polymer layers separated by an inorganic barrier layer.

10. The assembly according to claim 1, wherein the assembly is in the form of a roll.

11. The assembly according to claim 1, wherein the assembly is disposed on, above, or around a photovoltaic cell.

12. The assembly according to claim 11, wherein the photovoltaic cell is a CIGS cell.

13. A method of making the assembly according to claim 1, the method comprising:
providing the barrier assembly comprising the polymeric film substrate and the barrier film;
extruding the pressure sensitive adhesive by solventless extrusion; and
applying the pressure sensitive adhesive to the barrier assembly.

14. A method of making a photovoltaic module, the method comprising:
applying the assembly according to claim 1 to the front surface of a photovoltaic cell.

15. The method according to claim 14, wherein the photovoltaic cell comprises a flexible film substrate.

16. A pressure sensitive adhesive comprising:
a polyisobutylene having a weight average molecular weight less than 300,000 grams per mole; and
a hydrogenated hydrocarbon tackifier,
wherein the pressure sensitive adhesive is in the form of a film at least 0.25 mm thick.

17. A method of making a pressure sensitive adhesive, the method comprising:
hot melt extruding an extrudable composition comprising a polyisobutylene having a weight average molecular weight of at least 500,000 grams per mole and a hydrogenated hydrocarbon tackifier, wherein the hot melt extruding is carried out at a temperature sufficient to decrease the weight average molecular weight of the polyisobutylene resin to less than 300,000 grams per mole such that a pressure sensitive adhesive comprising a hydrogenated hydrocarbon tackifier and a polyisobutylene resin having a weight average molecular weight less than 300,000 grams per mole is formed.

18. The assembly according to claim 3, wherein the polyisobutylene has a weight average molecular weight of less than 300,000 grams per mole, and wherein the pressure sensitive adhesive further comprises a hydrogenated hydrocarbon tackifier.

19. The assembly according to claim 2, wherein the pressure sensitive adhesive comprises polyisobutylene.

20. The assembly according to claim 2, wherein the assembly is disposed on, above, or around a photovoltaic cell.
